(19) United States
(12) Patent Application Publication
(10) Pub. No.: US 2026/0143760 A1
(43) Pub. Date: May 21, 2026

(54) CHANNEL STRAIN ENHANCEMENT FOR STACKED MULTI-GATE DEVICES

(71) Applicant: Taiwan Semiconductor Manufacturing Company, Ltd., Hsin-Chu (TW)

(72) Inventors: Che Chi Shih, Taoyuan City (TW); Ku-Feng Yang, Baoshan Township (TW); Szuya Liao, Zhubei (TW)

(21) Appl. No.: 19/086,322

(22) Filed: Mar. 21, 2025

Related U.S. Application Data
(60) Provisional application No. 63/721,828, filed on Nov. 18, 2024.

(51) Int. Cl. H10D 30/69; H10D 30/00; H10D 30/01; H10D 30/43; H10D 62/10; H10D 62/83; H10D 62/832; H10D 64/23; H10D 84/01; H10D 84/85

(52) U.S. Cl. CPC H10D 30/797; H10D 30/014; H10D 30/0191; H10D 30/43; H10D 30/502; H10D 62/121; H10D 62/83; H10D 62/832; H10D 64/256; H10D 84/0167; H10D 84/017; H10D 84/0186; H10D 84/851

(57) ABSTRACT

Semiconductor devices and methods of forming the same are provided. An exemplary method includes forming a semiconductor layer stack over a substrate, the semiconductor layer stack having an upper channel layer over a lower channel layer, forming a semiconductor layer, the semiconductor layer comprising a lower portion inducing a compressive strain to the lower channel layer and an upper portion inducing a tensile strain to the upper channel layer, wherein the lower portion is spaced apart from the upper portion, after the forming of the semiconductor layer, forming a first gate structure wrapping around the upper channel layer and a second gate structure wrapping around the lower channel layer, removing the upper portion of the semiconductor layer, and after the forming of the first gate structure and the second gate structure, forming a source/drain feature coupled to the upper channel layer.

### PRIORITY DATA

This application claims priority to U.S. Provisional Patent Application Ser. No. 63/721,828, filed Nov. 18, 2024, the entire disclosure of which is hereby incorporated herein by reference.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs.

Such scaling down has also increased the complexity of processing and manufacturing ICs. For example, as integrated circuit (IC) technologies progress towards smaller technology nodes, multi-gate devices have been introduced to improve gate control by increasing gate-channel coupling, reducing off-state current, and reducing short-channel effects (SCEs). A multi-gate device generally refers to a device having a gate structure, or portion thereof, disposed over more than one side of a channel region. Fin-like field effect transistors (FinFETs) and gate-all-around (GAA) transistors are examples of multi-gate devices that have become popular and promising candidates for high performance and low leakage applications. A FinFET has an elevated channel wrapped by a gate on more than one side (for example, the gate wraps a top and sidewalls of a “fin” of semiconductor material extending from a substrate). A GAA transistor has a gate structure that can extend, partially or fully, around a channel region to provide access to the channel region on two or more sides. The channel region of a GAA transistor may be formed from nanowires, nanosheets, other nanostructures, and/or other suitable structures. The shapes of the channel region have also given a GAA transistor alternative names such as a nanosheet transistor or a nanowire transistor.

As the semiconductor industry further progresses into sub-10 nanometer (nm) technology process nodes in pursuit of higher device density, higher performance, and lower costs, challenges from both fabrication and design issues have led to stacked device structure configurations, such as complementary field effect transistors (CFETs) where an n-type multi-gate transistor and a p-type multi-gate transistor are stacked vertically, one over the other.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIGS. 1A and 1B illustrate a flow chart of a method for forming a semiconductor device including a vertical CFET, according to one or more aspects of the present disclosure.

FIGS. 2, 3, 4, 5, 6, 7, 8, 9, 10, 11, 12, 13, 14, 15, 16, 17, 18, 19, 20, 21, 22, 23, 24, 25, 26, 27, 28, and 29 illustrate fragmentary cross-sectional views of the semiconductor device during various fabrication stages in the method of FIGS. 1A-1B, according to various aspects of the present disclosure.

FIG. 30 illustrates a flow chart of an alternative method for forming a semiconductor device including a vertical CFET, according to one or more aspects of the present disclosure.

FIGS. 31, 32, 33, 34, and 35 illustrate fragmentary cross-sectional views of the semiconductor device during various fabrication stages in the method of FIG. 30, according to various aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art.

A stacked multi-gate device refers to a semiconductor device that includes a bottom multi-gate device and a top multi-gate device stacked over the bottom multi-gate device. When the bottom multi-gate device and the top multi-gate device are of different conductivity types, the stacked multi-gate device may be a complementary field effect transistor (CFET). The multi-gate devices in a CFET may be FinFETs or GAA transistors. The epitaxial growth environments for forming lower source/drain features (for the bottom multi-gate device) and upper source/drain features (for the top multi-gate device) of the CFET may not be exactly the same. For example, the top multi-gate device may be an n-type transistor, and the bottom multi-gate device may be a p-type transistor. The lower source/drain features (e.g., silicon germanium including p-type dopants) may be grown in a bottom-up way and thus grown with strain. Thus, hole mobility of the p-type transistor may be increased. However, the upper source/drain features may be formed over a dielectric structure (e.g., contact etch stop layer, interlayer dielectric layer) and on sidewall surfaces of upper nanostructures. During the epitaxial growth of the upper source/drain features, dislocations may form, resulting in strain relaxation. That is, electron mobility may not be increased.

The present disclosure provides methods of generating proper strain for both nanostructures of the bottom multi-gate device and nanostructures of the top multi-gate device. In an embodiment, a dummy layer is formed in a source/drain opening. The epitaxial growth duration of the dummy layer is controlled such that the dummy layer has a merged lower portion separated from a non-merged upper portion. The merged lower portion is grown from both substrate and sidewall surfaces of nanostructures of the lower multi-gate device and substantially fills a lower portion of the source/drain opening. Thus, the lower portion of the dummy layer will provide a compressive strain to nanostructures of the bottom multi-gate device. The non-merged upper portion is grown from sidewall surfaces of nanostructures of the upper multi-gate device and does not substantially fill an upper portion of the source/drain opening. Thus, the upper portion of the dummy layer will provide a tensile strain to nanostructures of the top multi-gate device. In an embodiment, the dummy layer includes silicon germanium, and treatment may be applied to the dummy layer to achieve germanium condensation in the dummy layer, thereby increasing the germanium concentration of the dummy layer to further enhance the strain. After forming functional gate structures to retain the proper strains in the channel regions, the dummy layer may be removed, and source/drain features will be then formed. Thus, both performance of the bottom multi-gate device and the top multi-gate device may be advantageously improved.

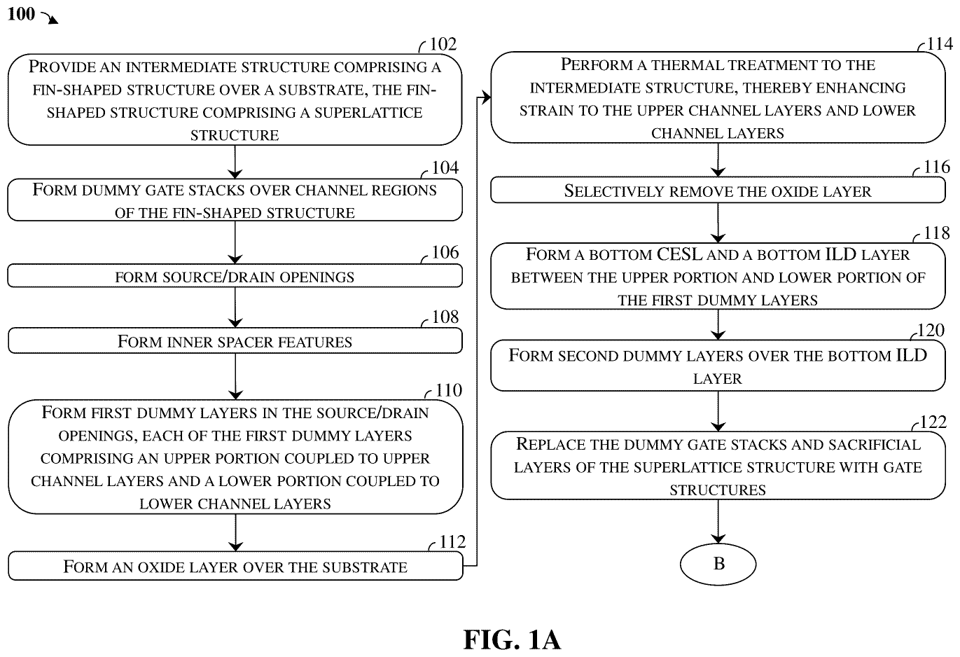

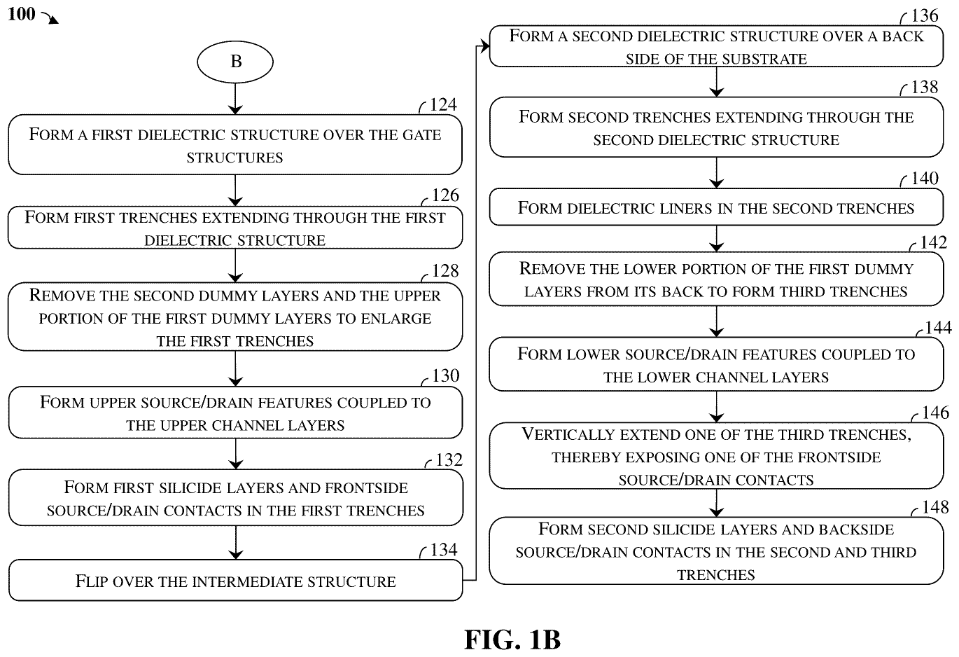

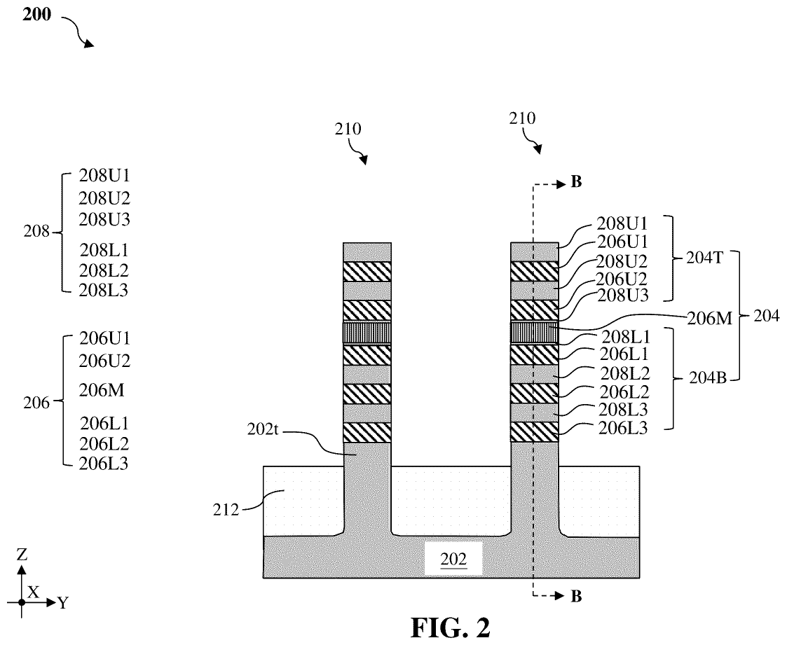

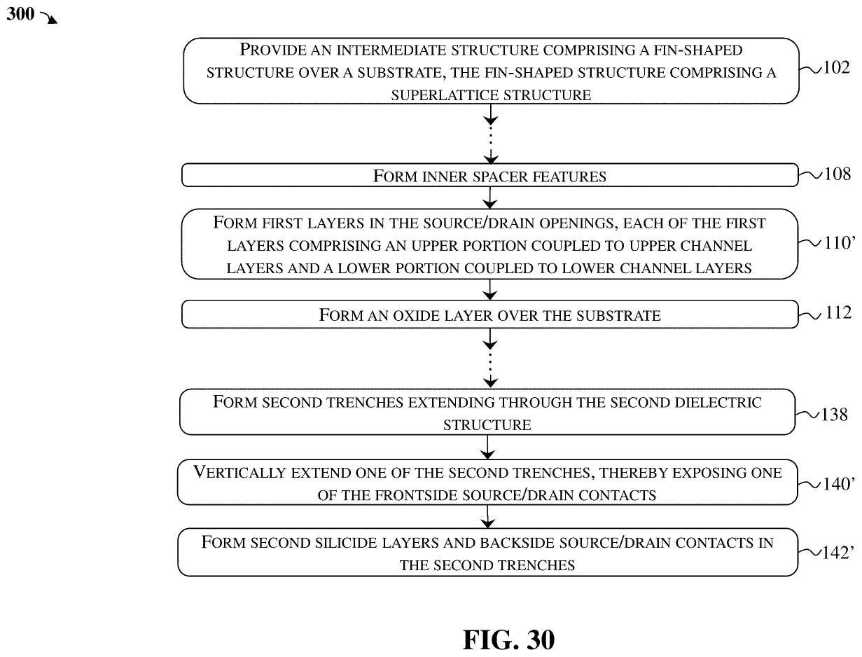

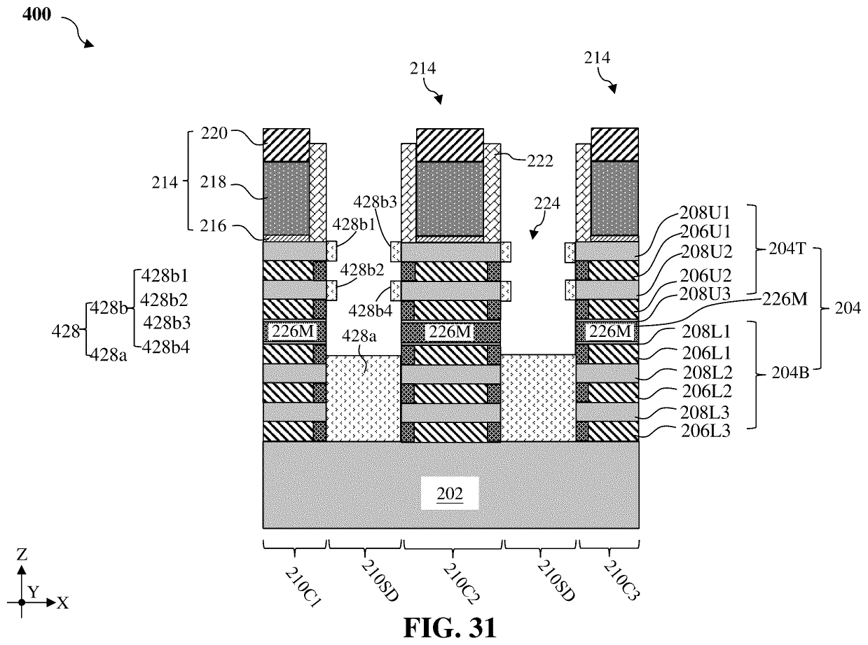

The various aspects of the present disclosure will now be described in more detail with reference to the figures. In that regard, FIGS. 1A-1B illustrate a flow chart of a method 100 for forming a semiconductor device including a vertical CFET, according to one or more aspects of the present disclosure. Method 100 is described below in conjunction with FIGS. 2-29, which are fragmentary cross-sectional views of an intermediate structure 200 at different stages of fabrication according to embodiments of method 100. Method 100 is merely an example and is not intended to limit the present disclosure to what is explicitly illustrated therein. Additional steps may be provided before, during and after method 100, and some steps described can be replaced, eliminated, or moved around for additional embodiments of the method. Not all steps are described herein in detail for reasons of simplicity. Because the intermediate structure 200 will be fabricated into a semiconductor device upon conclusion of the fabrication processes, the intermediate structure 200 may be referred to as the semiconductor device 200 as the context requires. FIG. 30 illustrate a flow chart of an alternative method 300 for forming a semiconductor device including a vertical CFET, according to one or more aspects of the present disclosure. Method 300 is described below in conjunction with FIGS. 31-35, which are fragmentary cross-sectional views of an intermediate structure 400 at different stages of fabrication according to embodiments of method 300. Method 300 is merely an example and is not intended to limit the present disclosure to what is explicitly illustrated therein. Additional steps may be provided before, during and after method 300, and some steps described can be replaced, eliminated, or moved around for additional embodiments of the method. Not all steps are described herein in detail for reasons of simplicity. Because the intermediate structure 400 will be fabricated into a semiconductor device upon conclusion of the fabrication processes, the intermediate structure 400 may be referred to as the semiconductor device 400 as the context requires. Additionally, throughout the present application and across different embodiments, like reference numerals denote like features with similar structures and compositions, unless otherwise excepted. For avoidance of doubts, the X, Y and Z directions in the figures are perpendicular to one another and are used consistently.

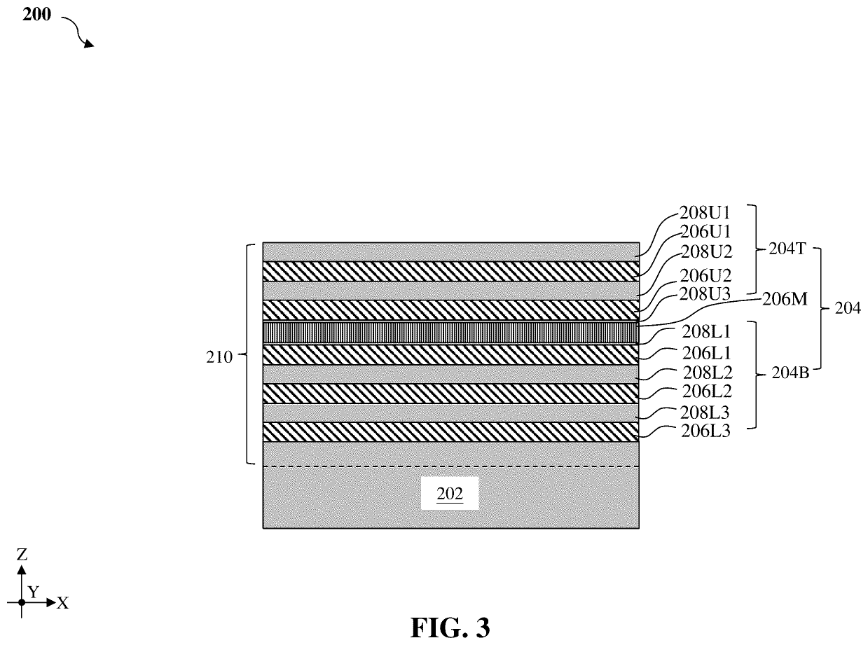

Referring now to FIGS. 1A and 2-3, method 100 includes a block 102 where an intermediate structure 200 is received. FIG. 2 depicts a cross-sectional view of the intermediate structure 200, and FIG. 3 depicts a cross-sectional view of the intermediate structure 200 taken along line B-B shown in FIG. 2. The intermediate structure 200 includes a substrate 202. In one embodiment, the substrate 202 may be a silicon (Si) substrate. In some other embodiments, the substrate 202 may include other semiconductors such as germanium (Ge), silicon germanium (SiGe), or a III-V semiconductor material. Example III-V semiconductor materials may include gallium arsenide (GaAs), indium phosphide (InP), gallium phosphide (GaP), gallium nitride (GaN), gallium arsenide phosphide (GaAsP), aluminum indium arsenide (AlInAs), aluminum gallium arsenide (AlGaAs), gallium indium phosphide (GalnP), and indium gallium arsenide (InGaAs). The substrate 202 may also include an insulating layer, such as a silicon oxide layer, to have a silicon-on-insulator (SOI) structure. Although not explicitly shown in the figures, the substrate 202 may include an n-type well region and a p-type well region for fabrication of transistors of different conductivity types. When present, each of the n-type well and the p-type well is formed in the substrate 202 and includes a doping profile. An n-type well may include a doping profile of an n-type dopant, such as phosphorus (P) or arsenic (As). A p-type well may include a doping profile of a p-type dopant, such as boron (B). The doping in the n-type well and the p-type well may be formed using ion implantation or thermal diffusion and may be considered portions of the substrate 202.

The intermediate structure 200 also includes fin-shaped structures 210 protruding from the substrate 202. In the present embodiments, the fin-shaped structure 210 is formed from a superlattice structure 204 and a portion of the substrate 202. The superlattice structure 204 may be deposited over the substrate 202 using an epitaxy process. Suitable epitaxy processes include vapor-phase epitaxy (VPE), ultra-high vacuum chemical vapor deposition (UHV-CVD), molecular beam epitaxy (MBE), and/or other suitable processes. The superlattice structure 204 includes a number of channel layers 208 interleaved by a number of sacrificial layers 206. The sacrificial layers 206 and the channel layers 208 are deposited alternatingly, one-after-another, to form the superlattice structure 204. The channel layers 208 and the sacrificial layers 206 may have different semiconductor compositions. In some implementations, the channel layers 208 are formed of silicon (Si) and sacrificial layers 206 are formed of silicon germanium (SiGe). In an embodiment, the germanium content of the sacrificial layers 206 is about 20% to about 50%. If the germanium content is less than about 20%, the etch selectivity between the sacrificial layers 206 and the channel layers 208 may not be high enough to allow selective removal or recess of the sacrificial layers 206 without inducing substantial damages to the channel layers 208; if the germanium content is greater than about 50%, the sacrificial layers 206 may include too many dislocations, affecting the characteristic of the channel layers 208 thereon.

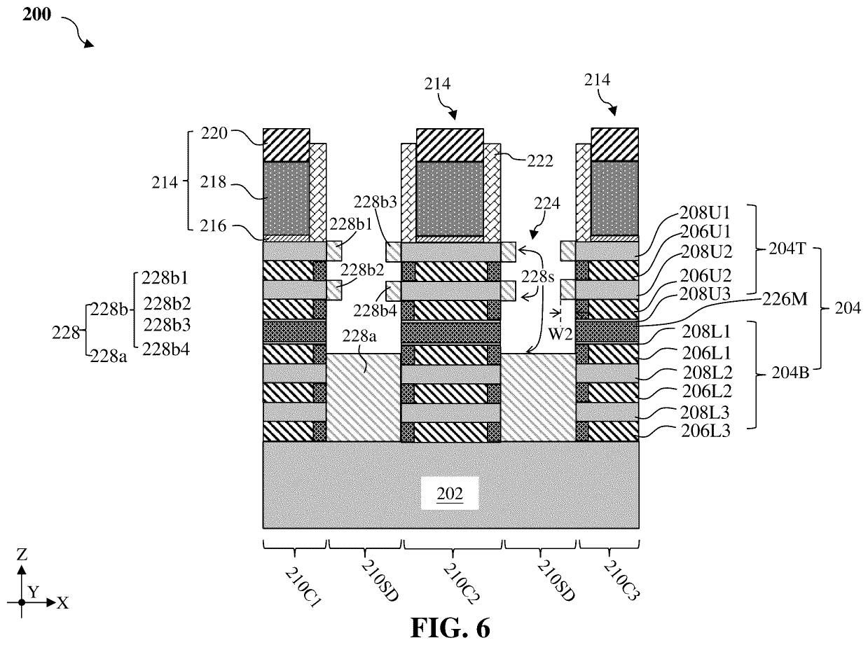

For case of references, the superlattice structure 204 may be vertically divided into a bottom portion 204B, a middle sacrificial layer 206M on the bottom portion 204B, and a top portion 204T on the middle sacrificial layer 206M. In this depicted example, the bottom portion 204B of the superlattice structure 204 includes channel layers 208L1, 208L2 and 208L3 interleaved by sacrificial layers 206L1, 206L2, and 206L3. The top portion 204T of the superlattice structure 204 includes channel layers 208U1, 208U2 and 208U3 interleaved by sacrificial layers 206U1 and 206U2. The channel layers 208L1, 208L2, 208L3, 208U1, 208U2, and 208U3 will provide nanostructures for the CFET. In some embodiments, the channel layers 208U1-208U2 will provide channel members for a top GAA transistor of the CFET, and the channel layers 208L2-208L3 will provide channel members for a bottom GAA transistor in the CFET. The term “channel member(s)” is used herein to designate any material portion for channel(s) in a transistor with nanoscale dimensions, and having an elongate shape, regardless of the cross-sectional shape of this portion. A germanium content of the middle sacrificial layer 206M may be different from the germanium content of other sacrificial layers (e.g., sacrificial layers 206U1-206U2, sacrificial layers 206L1-206L3) of the top portion 204T and bottom portion 204B. In some embodiments, a germanium content of the middle sacrificial layer 206M is greater than a germanium content of the other sacrificial layers 206U1-206U2 and 206L1-206L3 such that the entirety of the middle sacrificial layer 206M may be selectively removed during the formation of inner spacer recesses. In this present embodiment, the channel layers 208L1 and 208U3 are in direct contact with the middle sacrificial layer 206M, and a thickness of each of the channel layers 208L1 and 208U3 is less than a thickness of each of the channel layers 208U1-208U2 and 208L2-208L3 to facilitate the formation of a satisfactory first dummy layer (e.g., the first dummy layer 228 shown in FIG. 6).

It is noted that the superlattice structure 204 in FIGS. 2-3 includes six (6) layers of the channel layers 208 interleaved by six (6) layers of sacrificial layers 206, which is for illustrative purposes only and not intended to be limiting beyond what is specifically recited in the claims. It can be appreciated that any number of the channel layers 208 can be included in the superlattice structure 204 and distributed within the bottom portion 204B and the top portion 204T. The number of layers depends on the desired number of channels members for the top GAA transistor and the bottom GAA transistor. In some embodiments, the number of the channel layers 208 in the superlattice structure 204 may be between 4 and 10. The thicknesses of the channel layers 208 and the sacrificial layers 206 may be selected based on device performance considerations of the bottom GAA transistor, the top GAA transistor, and the CFET as a whole.

After forming the superlattice structure 204, the superlattice structure 204 and a portion of the substrate 202 are then patterned to form the fin-shaped structures 210. The patterned portion of the substrate 202 may be referred to as a protrusion 202t. The protrusion 202t may also be referred to a mesa or a base fin. For patterning purposes, a hard mask layer may be deposited over the superlattice structure 204. The hard mask layer may be a single layer or a multilayer. In one example, the hard mask layer includes a silicon oxide layer and a silicon nitride layer over the silicon oxide layer. As shown in FIGS. 2-3, each fin-shaped structure 210 extends vertically along the Z direction from the substrate 202 and extends lengthwise along the X direction. The fin-shaped structures 210 may be patterned using suitable processes including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a material layer is formed over a substrate and patterned using a photolithography process. Spacers are formed alongside the patterned material layer using a self-aligned process. The material layer is then removed, and the remaining spacers, or mandrels, may then be used as an etch mask to etch the superlattice structure 204 and the substrate 202 to form the fin-shaped structures 210.

The intermediate structure 200 also includes an isolation feature 212 (shown in FIG. 2) formed around the fin-shaped structures 210 to separate two adjacent fin-shaped structures 210. The isolation feature 212 may also be referred to as a shallow trench isolation (STI) feature 212. In an example process, a dielectric material for the isolation feature 212 is deposited over the intermediate structure 200, including the fin-shaped structure 210, using CVD, subatmospheric CVD (SACVD), flowable CVD, spin-on coating, and/or other suitable process. Then, the deposited dielectric material is planarized and recessed to form the isolation feature 212. As shown in FIG. 2, the fin-shaped structure 210 rises above the isolation feature 212. The dielectric material for the isolation feature 212 may include silicon oxide, silicon oxynitride, fluorine-doped silicate glass (FSG), a low-k dielectric, combinations thereof, and/or other suitable materials.

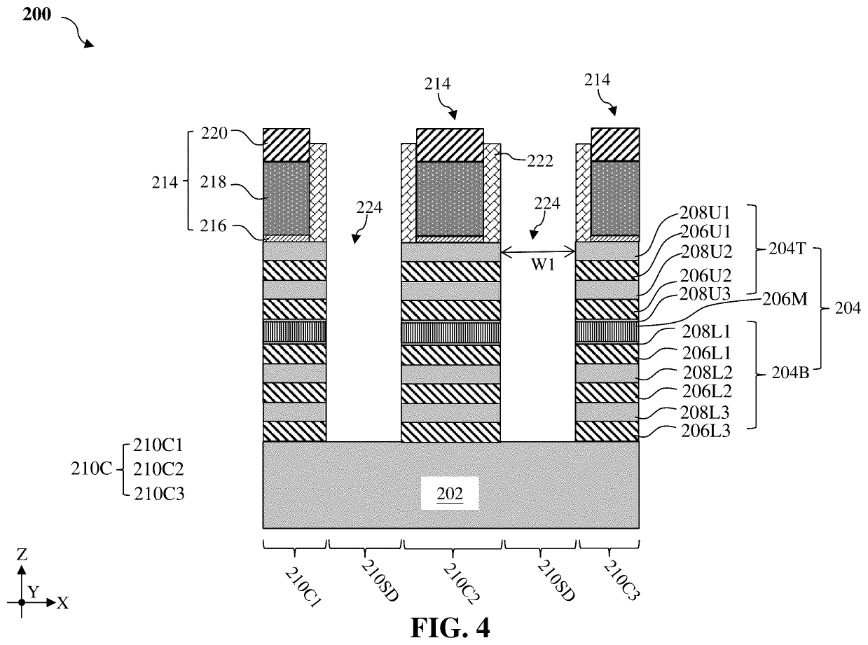

Referring to FIGS. 1A and 4, method 100 includes a block 104 where dummy gate stacks 214 are formed over channel regions of the fin-shaped structure 210. Three channel regions 210C1, 210C2, 210C3 are shown in the figures. The channel regions 210C1, 210C2, 210C3 may be collectively or separately referred to as channel region(s) 210C. In some embodiments, a gate replacement process (or gate-last process) is adopted where the dummy gate stack 214 serves as a placeholder for a functional gate structure. Other processes and configurations are possible. To form the dummy gate stack 214, a dummy dielectric layer 216, a dummy gate electrode layer 218, and a gate-top hard mask layer 220 are deposited over the intermediate structure 200. The deposition of these layers may include use of chemical vapor deposition (CVD), low-pressure CVD (LPCVD), plasma-enhanced CVD (PECVD), physical vapor deposition (PVD), atomic layer deposition (ALD), thermal oxidation, e-beam evaporation, other suitable deposition techniques, and/or combinations thereof. The dummy dielectric layer 216 may include silicon oxide, the dummy gate electrode layer 218 may include polysilicon, and the gate-top hard mask layer 220 may be a multi-layer structure that includes silicon oxide and silicon nitride. Using photolithography and etching processes, the gate-top hard mask layer 220 is patterned. The photolithography process may include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. The etching process may include dry etching, wet etching, and/or other etching methods. Like the fin-shaped structures 210, the dummy gate stack 214 may also be patterned using double-patterning or multiple-patterning techniques. Thereafter, using the patterned gate-top hard mask 220 as an etch mask, the dummy dielectric layer 216 and the dummy gate electrode layer 218 are then etched to form the dummy gate stack 214. The portion of the fin-shaped structure 210 underlying the dummy gate stack 214 defines a channel region 210C. The channel region 210C and the dummy gate stack 214 also define source/drain regions 210SD that are not vertically overlapped by the dummy gate stack 214. The channel region 210C is disposed between two source/drain regions 210SD along the Y direction. Source/drain region(s) may refer to a source region for forming a source and/or a drain region for forming a drain, individually or collectively dependent upon the context.

Still referring to FIGS. 1A and 4, method 100 includes a block 106 where source/drain regions 210SD of the fin-shaped structure 210 are recessed to form source/drain openings 224. Operations at block 106 may include formation of at least one gate spacer 222 over the sidewalls of the dummy gate stack 214 before the source/drain regions 210SD are recessed. In some embodiments, the formation of the at least one gate spacer 222 includes deposition of one or more dielectric layers over the intermediate structure 200. In an example process, the one or more dielectric layers are conformally deposited using CVD, SACVD, or ALD. The one or more dielectric layers may include silicon oxide, silicon nitride, silicon carbide, silicon oxynitride, silicon carbonitride, silicon oxycarbide, silicon oxycarbonitride, and/or combinations thereof. After the formation of the gate spacer 222, an etch process is performed to the intermediate structure 200 to form the source/drain openings 224. The etch process at block 106 may be a dry etch process or other suitable etch process. An example dry etch process may implement an oxygen-containing gas, hydrogen, a fluorine-containing gas (e.g., CF₄, SF₆, NF₃, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. As shown in FIG. 4, sidewalls of the sacrificial layers 206 and the channel layers 208 in the channel regions 210C are exposed in the source/drain openings 224. The source/drain opening 224 spans a width W1. The width W1 may be referred to as a distance between topmost channel layers 208U1 of two adjacent channel regions (e.g., 210C1 and 210C2).

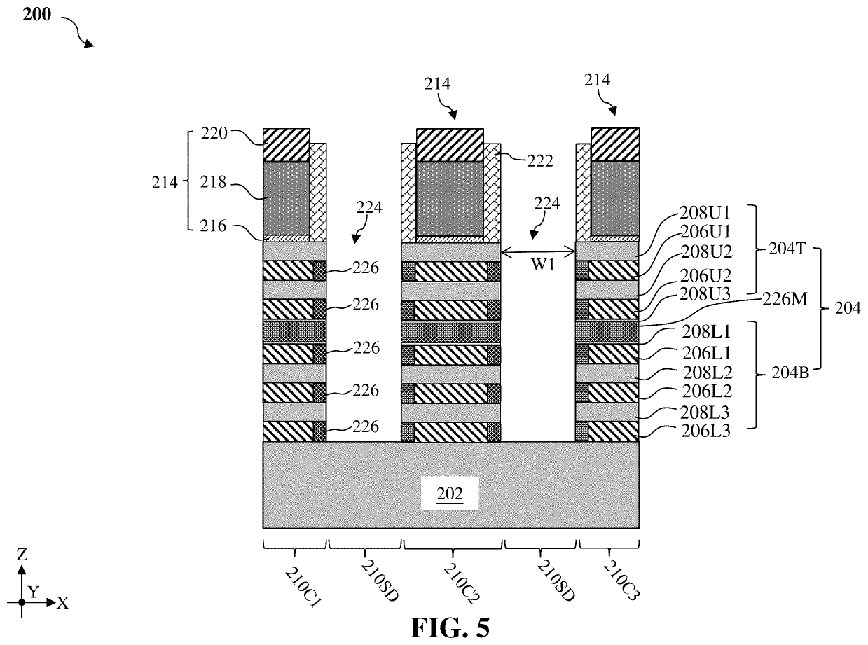

Referring to FIGS. 1A and 5, method 100 includes a block 108 where inner spacer features 226 are formed. At block 108, the sacrificial layers 206 exposed in the source/drain openings 224 are selectively and partially recessed to form inner spacer recesses, while the exposed channel layers 208 are substantially unetched. The middle sacrificial layer 206M, due to its greater germanium content, may be substantially removed during the formation of inner spacer recesses. In some embodiments, the selective recess may be a selective isotropic etching process (e.g., a selective dry etching process or a selective wet etching process), and the extent at which the sacrificial layers 206 are recessed is controlled by duration of the etching process. The selective dry etching process may include use of one or more fluorine-based etchants, such as fluorine gas or hydrofluorocarbons. The selective wet etching process may include use of hydrogen fluoride (HF) or ammonium hydroxide (NH₄OH). After the formation of the inner spacer recesses, an inner spacer material layer is deposited over the intermediate structure 200, including in the inner spacer recesses. Additionally, as shown in FIG. 5, the inner spacer material layer may also be deposited in the space left behind by selective removal of the middle sacrificial layer 206M. The inner spacer material layer may include silicon oxide, silicon nitride, silicon oxycarbide, silicon oxycarbonitride, silicon carbonitride, metal nitride, or a suitable dielectric material. In an embodiment, the inner spacer material layer includes silicon oxycarbonitride having a carbon content that is less than about 6%. The deposited inner spacer material layer is then etched back to remove excess portions of the inner spacer material layer over the dummy gate stack 214, the gate spacer 222, and sidewalls of the channel layers 208, thereby forming the inner spacer features 226 and the middle dielectric layer 226M, as shown in FIG. 5.

Referring to FIGS. 1A and 6, method 100 includes a block 110 where first dummy layers 228 are formed in the source/drain openings 224. After forming the inner spacer features 226, the first dummy layers 228 are formed in the source/drain openings 224. The first dummy layers 228 have a composition different than the channel layers 208 such that strains may be induced to the channel layers 208. The first dummy layers 228 may include semiconductor materials. In an embodiment, the first dummy layers 228 include silicon germanium. In an embodiment, germanium concentration of the first dummy layer 228 is about 20% to about 50%. If the germanium concentration is less than 20%, then crystal lattice mismatch between the first dummy layer 228 and the channel layers 208 may not be large enough to generate satisfactory strain; and if the germanium concentration is higher than about 50%, there will be more defects formed and thus a higher dislocation density within the first dummy layer 228. Those higher dislocation density may limit a growth thickness of the first dummy layer 228. In an embodiment, the first dummy layer 228 includes undoped silicon germanium. In another embodiment, the first dummy layer 228 may include doped silicon germanium, and dopants may include B, P, As, C, Sb, Ga, or other suitable materials. The dopant concentration may be between about 1E18 atoms/cm3 and 1E22 atoms/cm3. Introducing dopants may increase etch selectivity between the first dummy layer 228 and other features.

An epitaxial process, such as VPE, UHV-CVD, MBE, and/or other suitable processes, is performed to form the first dummy layer 228 in the source/drain opening 224. The epitaxial growth process may use gaseous and/or liquid precursors (e.g., SiH₄, Si₂H₆, SiH₂Cl₂, GeH₄, Ge₂H₆, HCl, Cl₂), which interact with the composition of the substrate 202 as well as the channel layers 208. A process temperature of the epitaxial process may be between about 400° C. and about 800° C. If the process temperature is greater than 800° C., a large amount of germanium may diffuse into the channel layers, disadvantageously affecting the device performance; if the process temperature is lower than 400° C., the growth rate for forming the first dummy layer 228 may be too low, and it may take longer time to form the first dummy layer 228 with a satisfactory thickness.

The epitaxial growth of first dummy layers 228 may take place from both the exposed top surface of the substrate 202 and the exposed sidewalls of the lower channel layers 208L2 and 208L3 and upper channel layers 208U1-208U2. For example, the first dummy layer 228 includes a lower portion 228a epitaxially grown from the exposed top surface of the substrate 202 and the exposed sidewalls of the lower channel layers 208L2 and 208L3 and an upper portion 228b epitaxially grown from the exposed sidewalls of the upper channel layers 208U1-208U2. The epitaxial growth process may be stopped until a top surface of the lower portion 228a is above a bottom surface of the sacrificial layer 206L1 and below a top surface of the sacrificial layer 206L1. As represented by FIG. 6, the lower portion 228a of the first dummy layer 228 substantially fills a lower portion of the source/drain opening 224 and generates compressive strain to the lower channel layers 208L2 and 208L3.

Since a growth rate from (100) direction is greater than a growth rate from (110) direction, upon completion of the epitaxial growth, the upper portion 228b spans a width less than a width of the lower portion 228a. For example, the lower portion 228a extends from a channel region 210C1 to a channel region 210C2. In this illustrated embodiment, the upper portion 228b of the first dummy layer 228 includes two first parts 228b1 and 228b3 on the exposed sidewalls of the channel layer 208U1 in the channel region 210C1 and the channel layer 208U1 in the channel region 210C2. The upper portion 228b of the first dummy layer 228 also includes two second parts 228b2 and 228b4 on the exposed sidewalls of the channel layer 208U2 in the channel region 210C1 and the channel layer 208U2 in the channel region 210C2. The two first parts 228b1 and 228b3 are not merged, the two second parts 228b2 and 228b4 are not merged. Each part of the upper portion 228b generates a tensile strain to the corresponding upper channel layer (e.g., channel layer 208U1 or channel layer 208U2) in a corresponding channel region (e.g., 210C1 or 210C2). Each part (e.g., 228b1/228b2/228b3/228b4) of the upper portion 228b spans a width W2. A ratio of the width W2 to the width W1 may be between about 5% and about 40% such that each part of the upper portion can provide strain to corresponding channel layer without worrying about strain relaxation. In an embodiment, the width W2 is about Inm to about 10 nm.

The epitaxial growth of first dummy layers 228 may also take place from the exposed sidewalls of the channel layers 208U3 and 208L1. However, since the channel layers 208U3 and 208L1 are much thinner than other channel layers, the portion of the first dummy layers on the sidewalls of the channel layers 208U3 and 208L1 are dimensional smaller than the parts 228b1 and 228b2 and may be fully oxidized and then removed during subsequent processes (e.g., operations at block 114 and 116), and thus, such parts of the first dummy layers 228 are not explicitly shown in the figures. For case of description, surfaces of the first dummy layers 228 that are not covered are referred to as an outer surface 228s. For example, the outer surface 228s of the first dummy layer 228 includes a top surface of the lower portion 228a, one sidewall of each of the parts 228b1, 228b2, 228b3, 228b4, and top and bottom surfaces of each of the parts 228b1, 228b2, 228b3, 228b4.

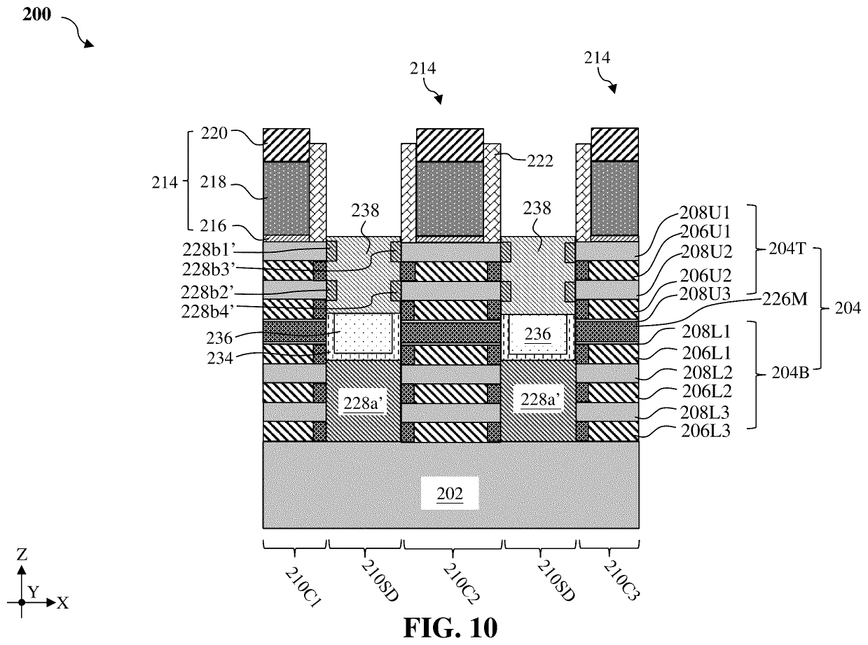

In some existing technologies, a blocking layer (not shown) may be deposited over the intermediate structure 200 to cover sidewalls of the top portion 204T of the superlattice structure 204. The blocking layer may also cover sidewalls of the middle dielectric layer 226M and the channel layer 208L1. The blocking layer may include dielectric materials. After the formation of the blocking layer, lower source/drain features may be formed. The blocking layer, due to its dielectric composition, blocks formation of the lower source/drain features on sidewalls of the channel layers 208U1-208U3 and 208L1. Upper source/drain features are formed after forming an isolation structure (e.g., a bottom contact etch stop layer 234 and a bottom ILD layer 236 shown in FIG. 10) and after removing the blocking layer. The upper source/drain feature substantially fills an upper portion of the source/drain opening, extends from one channel region (e.g., the channel region 210C1) to another channel region (e.g., the channel region 210C2) and may span a width substantially equal to the width W1. The upper source/drain feature in existing technologies cannot provide tensile strain to the channel layers 208U1-208U2. In the present disclosure, the upper portion 228b includes the part 228b1 separated from the part 228b3, and the part 228b2 separated from the part 228b4. Thus, strain stress will not be substantially relaxed, and the upper portion 228b can exert tensile strain to the channel layers 208U1-208U2.

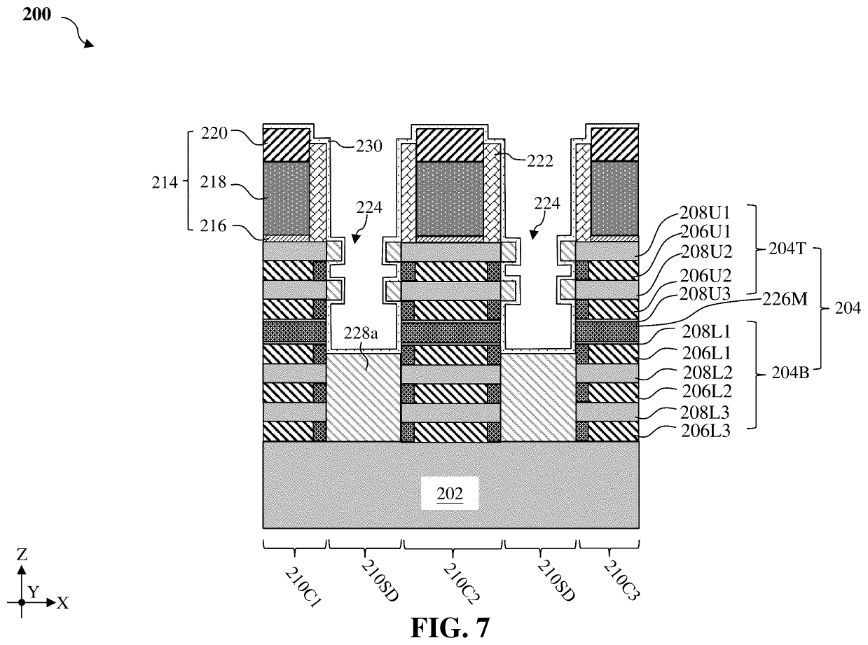

Referring to FIGS. 1A and 7, method 100 includes a block 112 where an oxide layer 230 is formed over the intermediate structure 200. To enhance the compressive strain to the lower channel layers and enhance the tensile strain to the upper channel layers, germanium concentration of the first dummy layer may be increased. In this illustrated embodiment, the oxide layer 230 is conformally deposited over the intermediate structure 200, including on exposed surfaces of the first dummy layers 228, using atomic layer deposition (ALD), thermal ALD, or plasma-enhanced ALD (PEALD). The process temperature of the deposition process may be between about 25° C. and about 600° C. A deposition thickness of the oxide layer 230 may be about 0.5 nm to about 10 nm. The oxide layer 230 may include silicon oxide or other suitable oxygen-containing dielectric layer. It is noted that some parts of the oxide layer 230 may be merged, depending on the deposition thickness of the oxide layer 230. For example, a part of the oxide layer 230 extending along a sidewall of the part 228b1 and a part of the oxide layer 230 extending along a sidewall of the part 228b3 may merge.

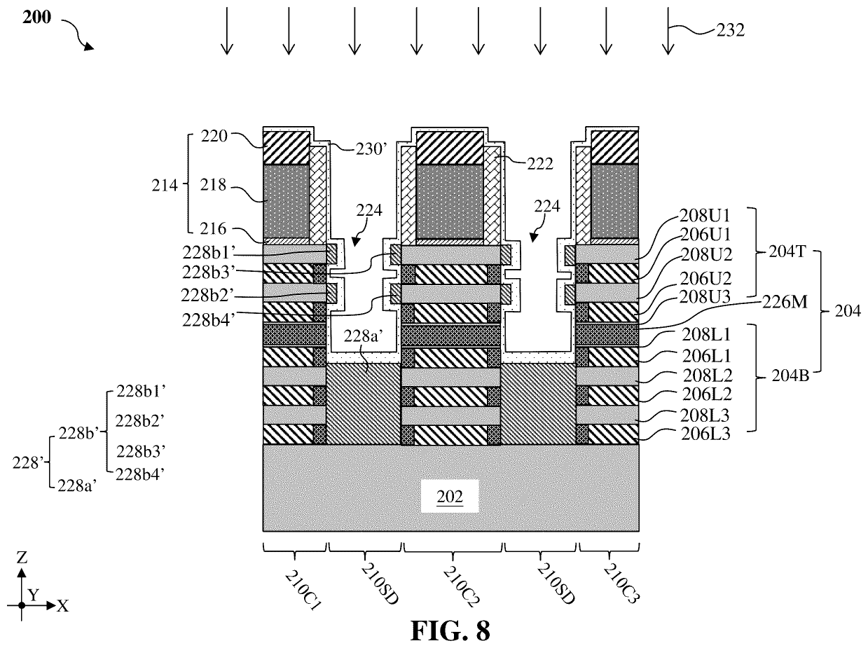

Referring to FIGS. 1A and 8, method 100 includes a block 114 where a thermal treatment 232 is performed to the intermediate structure 200. The thermal treatment 232 may induce germanium in the first dummy layer 228 to diffuse towards adjacent features. For example, germanium in the upper portion 228b of the first dummy layer 228 may diffuse from its outer surface 228s towards inward and towards the channel layers 208U1-208U2, and germanium in the lower portion 228a of the first dummy layer 228 may diffuse downward and towards the substrate 202. Due to the diffusion of the germanium near the outer surface 228s and the existence of the oxide layer 230, silicon in the first dummy layer 228 near the outer surface 228s may be oxidized, thereby forming an oxidized layer. The oxidized layer may include silicon oxide. The oxide layer 230 and the oxidized layer are collectively referred to as an oxide layer 230′. As a result, the oxide layer 230′ has a non-uniform thickness, as represented by FIG. 8. The oxidization consumes silicon of the first dummy layer 228. As a result, the germanium concentration of the first dummy layer 228 is increased. In other words, the performing of the thermal treatment 232 forms the oxide layer 230′ and causes condensation of germanium within the first dummy layer 228. The first dummy layer 228 after the performing of the thermal treatment 232 is referred to as the first dummy layer 228′. A germanium concentration of the first dummy layer 228′ is greater than the first dummy layer 228 prior to the performing of the thermal treatment 232. In an embodiment, the germanium concentration of the first dummy layer 228′ may be about 50% to about 100%. Due to the lattice mismatch between germanium and silicon and condensation of germanium, this first dummy layer 228′ can exert more compressive strain to the lower channel layers 208L2 and 208L3 and more tensile strain to the upper channel layers 208U1 and 208U2.

A thickness of the first dummy layer 228′ is less than a thickness of the first dummy layer 228 that has not undergone the operations at block 114. More specifically, the first dummy layer 228′ includes a lower portion 228a′ having a thickness less than the lower portion 228a, an upper portion 228b′ having a part 228bl′ in direct contact with the channel layer 208U1 in one channel region (e.g. the channel region 210C1), a part 228b2′ in direct contact with the channel layer 208U2 in one channel region, a part 228b3′ in direct contact with the channel layer 208U1 in another channel region (e.g. the channel region 210C2), a part 228b4′ in direct contact with the channel layer 208U2 in another channel region. Each of the parts 228b1′-228b4′ each has a reduced width along the X direction than the corresponding part 228b1-228b4, respectively. In an embodiment, the top surface of the lower portion 228a′ is above a top surface of the channel layer 208L2.

In an embodiment, the thermal treatment 232 includes an anneal process. The anneal process may include flash anneal, cyclic anneal, or spike anneal in presence of an oxygen source such as oxygen or water vapor (i.e., steam). For example, the anneal process may be performed under a gas condition including a combination of oxygen, hydrogen, nitrogen and argon. In some instances, the anneal process includes an anneal temperature between about 300° C. and about 900° C. and may include about 1 to 20 cycles. If the anneal temperature is higher than 900° C. or the duration of the anneal process is too long, some features of the intermediate structure 200 may melt; if the anneal temperature is lower than 300° C. or if the duration of anneal process is too short, interdiffusion of silicon and germanium may be too little, and silicon in the first dummy layer 228 near the outer surface 228s may not be oxidized.

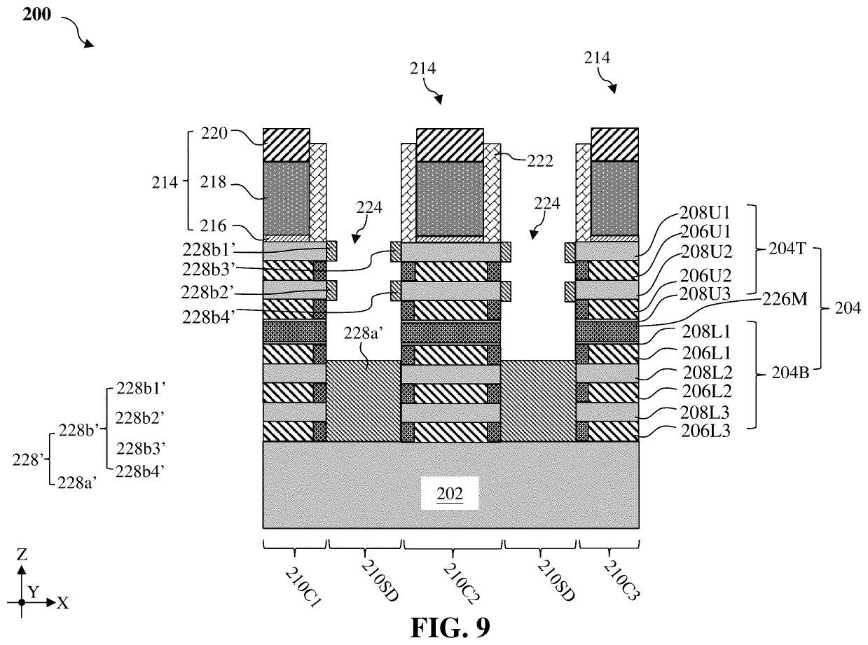

Referring to FIGS. 1A and 9, method 100 includes a block 116 where the oxide layer 230′ is selectively removed. After performing the thermal treatment 232, the oxide layer 230′ is selectively removed. The removal of the oxide layer 230′ exposes the first dummy layer 228′ thereunder. In some embodiments, the oxide layer 230′ may be selectively removed using a selective dry etch or a selective wet etch that uses, for example, ammonium hydroxide (NH₄OH).

Referring to FIGS. 1A and 10, method 100 includes a block 118 where a bottom contact etch stop layer (CESL) 234 and a bottom interlayer dielectric (ILD) layer 236 are formed between the upper portion 228b′ and the lower portion 228a′ of the first dummy layers 228′. The bottom CESL 234 may include silicon nitride, silicon oxynitride, and/or other materials and may be formed by CVD, ALD, plasma-enhanced chemical vapor deposition (PECVD) process and/or other suitable deposition or oxidation processes. In an embodiment, the bottom CESL 234 includes silicon nitride. In some embodiments, the bottom CESL 234 is first conformally deposited on the intermediate structure 200 and the bottom ILD layer 236 is deposited over the bottom CESL 234 by spin-on coating, flowable CVD (FCVD), CVD, or other suitable deposition technique. The bottom ILD layer 236 may include materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The bottom CESL 234 and the bottom ILD layer 236 may be etched back to exposed sidewalls of the upper portion 228b′ of the first dummy layer 228′. In embodiments presented by FIG. 10, after being etched back, top surfaces of the bottom CESL 234 and the bottom ILD layer 236 are above a top surface of the channel layer 208U3.

Still referring to FIGS. 1A and 10, method 100 includes a block 120 where second dummy layers 238 are formed in the source/drain openings 224. After forming the bottom ILD layer 236, an epitaxial process, such as VPE, UHV-CVD, MBE, and/or other suitable processes, is performed to form the second dummy layer 238 in the source/drain opening 224. The epitaxial growth process may use gaseous and/or liquid precursors, which interact with the composition of the upper portion 228b′ of the first dummy layer 228′. The epitaxial growth process may be stopped when the second dummy layer 238 substantially fills a remaining portion of the source/drain opening 224. In an embodiment, the second dummy layer 238 include silicon germanium. The second dummy layer 238 and the first dummy layer 228′ may have same germanium concentration or different germanium concentrations. The second dummy layer 238 may be undoped. In some other embodiments, the second dummy layer 238 may include a dopant, such as phosphorus (P) or arsenic (As).

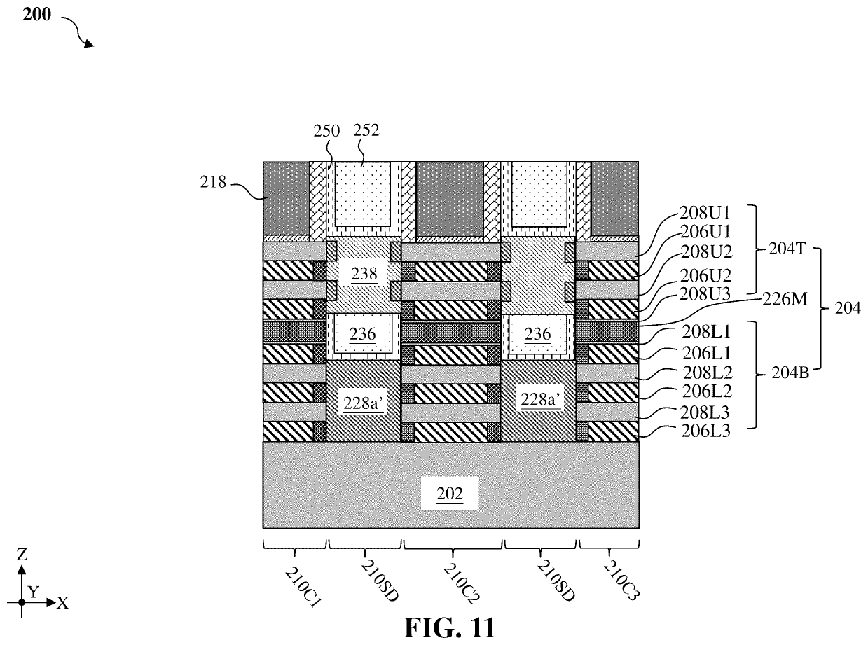

Referring to FIGS. 1A and 11-12, method 100 includes a block 122 where the dummy gate stacks 214 and the sacrificial layers 206 of the superlattice structure 204 are replaced with gate structures 254. With reference to FIG. 11, after forming the second dummy layers 238, a top CESL 250 and a top ILD layer 252 are deposited over the second dummy layers 238. The top CESL 250 may include silicon nitride, silicon oxynitride, and/or other materials known in the art and may be formed by CVD, ALD, plasma-enhanced chemical vapor deposition (PECVD) process and/or other suitable deposition or oxidation processes. In some embodiments, the top CESL 250 is first conformally deposited on the intermediate structure 200 and the top ILD layer 252 is then deposited over the top CESL 250 by spin-on coating, FCVD, CVD, or other suitable deposition technique. The top ILD layer 252 may include materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. In some embodiments, after formation of the top ILD layer 252, the intermediate structure 200 may be annealed to improve integrity of the top ILD layer 252. To remove excess materials and to expose top surfaces of the dummy gate electrode layers 218, a planarization process, such a chemical mechanical polishing (CMP) process may be performed.

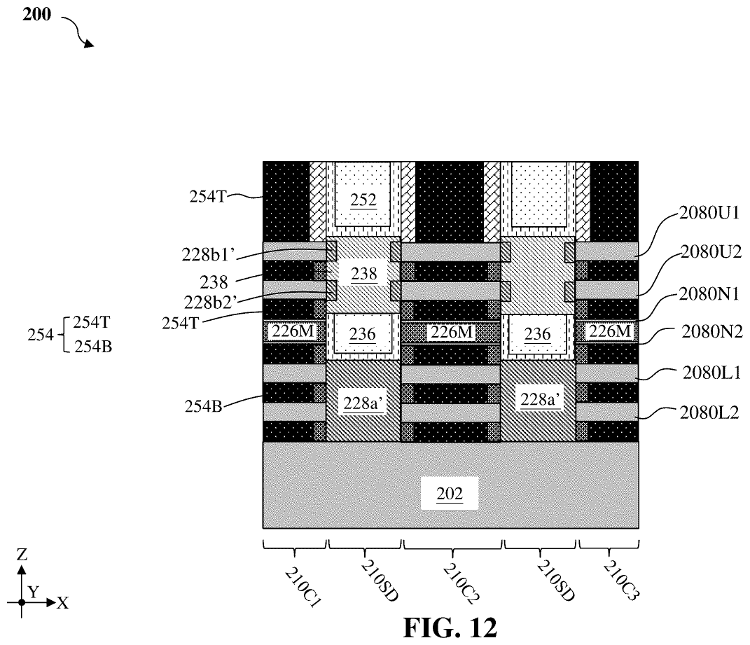

With reference to FIGS. 11-12, operations at block 122 may also include removal of the dummy gate stacks 214, release of the channel layers 208 as channel members (including upper channel members 2080U1-2080U2, and lower channel members 2080L1-2080L2) and nanostructures (including the nanostructures 2080N1 and 2080N2). The removal of the dummy gate stacks 214 may include one or more etching processes that are selective to the material in the dummy gate stacks 214. For example, the removal of the dummy gate stacks 214 may be performed using as a selective wet etch, a selective dry etch, or a combination thereof. After the removal of the dummy gate stacks 214, sidewalls of the channel layers 208 and sacrificial layers 206 in the channel regions 210C are exposed. Thereafter, the sacrificial layers 206 in the channel regions 210C are selectively removed to release the channel layers 208 as the channel members (including the upper channel members 2080U1-2080U2, the lower channel members 2080L1-2080L2) and nanostructures (including the nanostructures 2080N1 and 2080N2). The selective removal of the sacrificial layers 206 may be implemented by a selective dry etch, a selective wet etch, or other selective etch processes. In some embodiments, the selective wet etching includes an APM etch (e.g., ammonia hydroxide-hydrogen peroxide-water mixture). In embodiments represented by FIG. 12, the nanostructures 2080N1 and 2080N2 are in direct contact with the middle dielectric layer 226M.

With the release of the channel members (e.g., channel members 2080U1, 2080U2, 2080L1, 2080L2), a gate structure 254 is deposited to wrap around each of the channel members. While not explicitly shown in the figures, the gate structure 254 includes an interfacial layer to interface the channel members, a gate dielectric layer over the interfacial layer, a p-type work function layer, or an n-type work function layer. In some embodiments, the interfacial layer includes silicon oxide and may be formed in a pre-clean process. An example pre-clean process may include use of RCA SC-1 (ammonia, hydrogen peroxide and water) and/or RCA SC-2 (hydrochloric acid, hydrogen peroxide and water). The gate dielectric layer is then deposited over the interfacial layer using ALD, CVD, and/or other suitable methods. The gate dielectric layer is formed of high-K dielectric materials. As used and described herein, high-k dielectric materials include dielectric materials having a high dielectric constant, for example, greater than that of thermal silicon oxide (˜3.9). The gate dielectric layer may include hafnium oxide. Alternatively, the gate dielectric layer may include other high-K dielectrics, such as titanium oxide (TiO₂), hafnium zirconium oxide (HfZrO), tantalum oxide (Ta₂O₅), hafnium silicon oxide (HfSiO4), zirconium oxide (ZrO₂), zirconium silicon oxide (ZrSiO2), lanthanum oxide (La₂O₃), aluminum oxide (Al₂O₃), zirconium oxide (ZrO), yttrium oxide (Y₂O₃), SrTiO₃ (STO), BaTiO₃ (BTO), BaZrO, hafnium lanthanum oxide (HfLaO), lanthanum silicon oxide (LaSiO), aluminum silicon oxide (AlSiO), hafnium tantalum oxide (HfTaO), hafnium titanium oxide (HfTiO), (Ba,Sr) TiO₃ (BST), silicon nitride (SiN), silicon oxynitride (SiON), combinations thereof, or other suitable material.

After the deposition of the gate dielectric layer, the n-type work function layer and the p-type work function layer may be sequentially deposited. The p-type work function and the n-type work function layer may include a single layer or alternatively a multi-layer structure, such as various combinations of a metal layer with a selected work function to enhance the device performance (work function metal layer). By way of example, the p-type work function layer may include titanium nitride (TiN), tantalum nitride (TaN), ruthenium (Ru), molybdenum (Mo), aluminum (Al), tungsten nitride (WN), zirconium silicide (ZrSi₂), molybdenum silicide (MoSi₂), tantalum silicide (TaSi₂), nickel silicide (NiSi₂), other p-type work function material, or combinations thereof. The n-type work function layer may include titanium (Ti), aluminum (Al), silver (Ag), manganese (Mn), zirconium (Zr), titanium aluminum (TiAl), titanium aluminum carbide (TiAlC), tantalum carbide (TaC), tantalum carbonitride (TaCN), tantalum silicide nitride (TaSiN), tantalum aluminum (TaAl), tantalum aluminum carbide (TaAlC), titanium aluminum nitride (TiAlN), other n-type work function material, or combinations thereof. The gate structure 254 may also include a liner layer, a wetting layer, an adhesion layer, a metal alloy or a metal silicide. The gate structure 254 may also include a metal fill to reduce contact resistance. In some instance, the metal fill includes tungsten (W).

In some embodiments, the gate structure 254 may be a common gate structure that wraps around both the upper channel members 2080U1-2080U2 and the lower channel members 2080L1-2080L2. In some other embodiments depicted in the drawings, the gate structure 254 includes a bottom gate portion 254B wrapping around the lower channel members 2080L1-2080L2 and a top gate portion 254T wrapping around the upper channel members 2080U1-2080U2. The bottom gate portion 254B and the top gate portion 254T have different work function layers. For example, the top gate portion 254T may include n-type work function layer(s) and the bottom gate portion 254B may include p-type work function layer(s). When the gate structure 254 includes a bottom gate portion 254B and a top gate portion 254T, the two gate portions may be electrically isolated from each other.

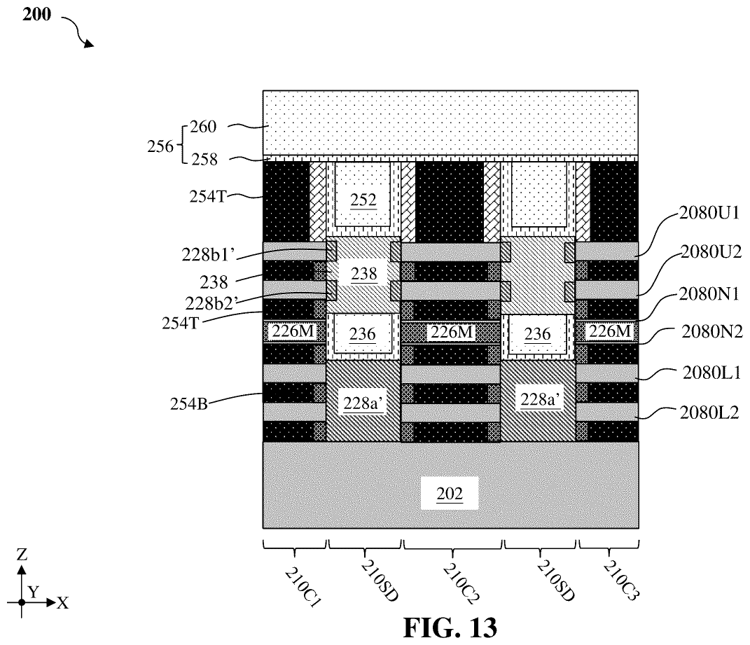

Referring to FIGS. 1B and 13, method 100 includes a block 124 where a first dielectric structure 256 is formed over the gate structures 254. The first dielectric structure 256 may include an etch stop layer 258 and an interlayer dielectric (ILD) layer 260 deposited over the etch stop layer 258. The etch stop layer 258 may include silicon nitride, silicon oxynitride, and/or other suitable materials and may be formed by ALD, plasma-enhanced chemical vapor deposition (PECVD) process and/or other suitable deposition or oxidation processes. The etch stop layer 258 may indicate an etch stop point for forming gate via openings over the gate structures 254. The ILD layer 260 may include materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials and may be deposited by, for example, a PECVD process or other suitable deposition technique after the deposition of the etch stop layer 258. After the deposition of the ILD layer 260, a planarization process, such a chemical mechanical polishing (CMP) process may be performed to provide a planar top surface.

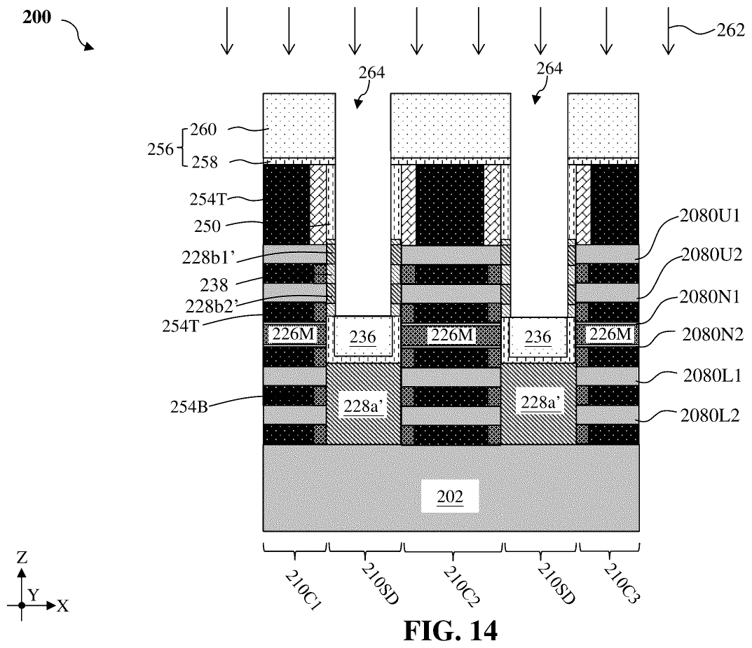

Referring to FIGS. 1B and 14, method 100 includes a block 126 where first trenches 264 are formed to extend through the first dielectric structure 256. In an embodiment, a masking element (not shown) is formed on the first dielectric structure 256. In some embodiments, the masking element may include a hard mask layer and/or a photoresist layer. The masking element is patterned to have openings disposed directly over the second dummy layers 238. While using the masking element as an etch mask, a first etching process 262 is performed to remove portions of the first dielectric structure 256, the top CESL 250 and top ILD layer 252, and the second dummy layer 238 disposed directly under the openings, thereby forming the first trenches 264. The first etching process 262 may be an anisotropic etching process. As illustrated by FIG. 14, each trench 264 exposes a top surface of the bottom ILD layer 236. In some embodiments, depending on the dimension of the openings of the masking element, the first trenches 264 may or may not expose the upper portion 228b′ of the first dummy layer 228′.

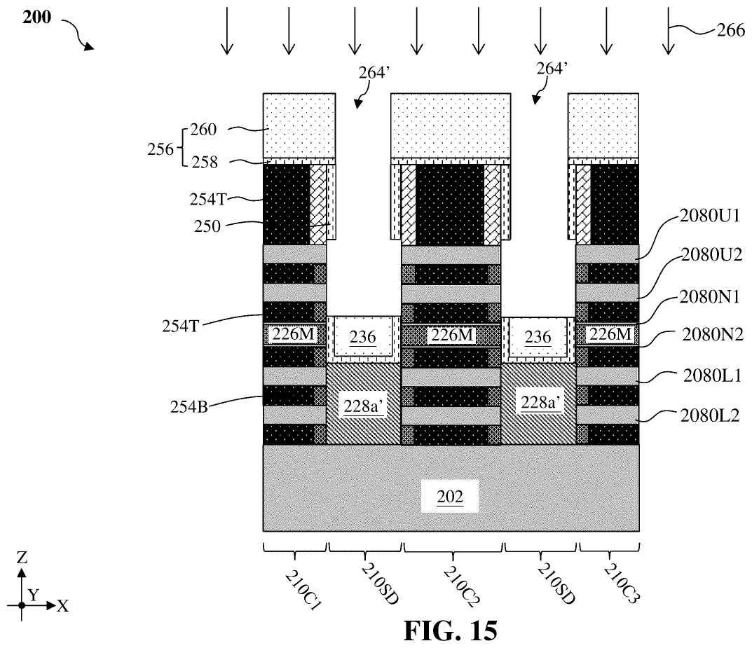

Referring to FIGS. 1B and 15, method 100 includes a block 128 where the second dummy layers 238 and the upper portion 228b′ of the first dummy layers 228′ are selectively removed. As described above, the first etching process 262 removes portions of the second dummy layer 238 disposed directly under the openings of the masking element. After forming the first trenches 264, a second etching process 266 is performed to selectively remove the upper portion 228b′ of the first dummy layer 228′ and a remaining portion of the second dummy layer 238 without substantially etching the upper channel members 2080U1-2080U2 and inner spacer features 226. Etchant of the second etching process 266 may not substantially etch the first dielectric structure 256, the bottom CESL 234 and top CESL 250, and the bottom ILD layer 236 and top ILD layer 252. In an embodiment, the second etching process 266 is an isotropic etching process. The performing of the second etching process 266 enlarges a lower portion of the first trench 264. The enlarged first trench 264 may be referred to as the first trenches 264′. After performing the second etching process 266, the masking element may be selectively removed.

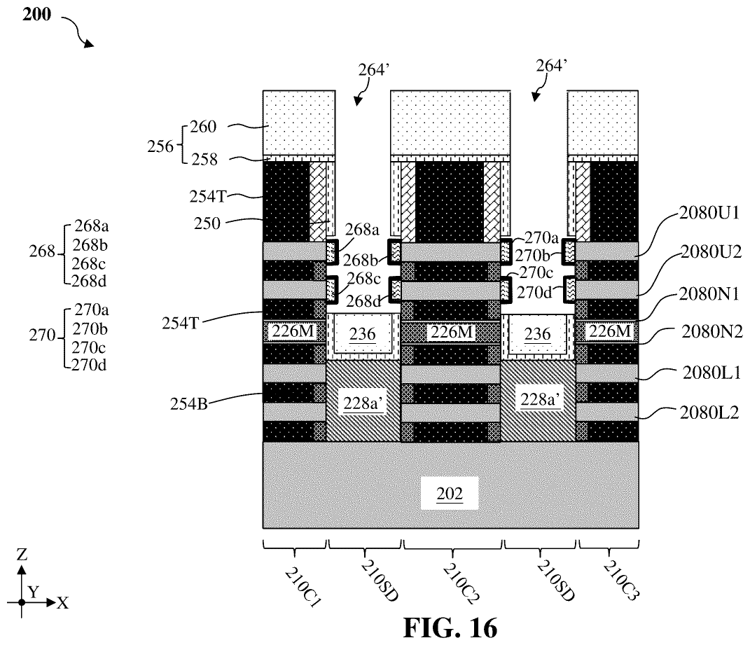

Referring to FIGS. 1B and 16, method 100 includes a block 130 where upper source/drain features 268 are formed. The selective removal of the upper portion 228b′ of the first dummy layer 228′ exposes sidewalls of the upper channel members 2080U1-2080U2. Upper source/drain features 268 may be formed in the trenches 264′ using an epitaxial process, such as VPE, UHV-CVD, MBE, and/or other suitable processes. The epitaxial growth process may use gaseous and/or liquid precursors, which interact with the composition of the upper channel members 2080U1-2080U2. As illustrated in FIG. 16, the upper source/drain features 268 are in physical contact with (or adjoining) the upper channel members 2080U1 and 2080U2. Depending on the design, the upper source/drain features 268 may be n-type or p-type. In the depicted embodiments, the upper source/drain features 268 are n-type source/drain features and may include silicon, phosphorus-doped silicon, arsenic-doped silicon, antimony-doped silicon, or other suitable material and may be in-situ doped during the epitaxial process by introducing an n-type dopant, such as phosphorus, arsenic, or antimony, or ex-situ doped using a junction implant process. A dopant concentration of the upper source/drain features 268 may be greater than about 1E21 atoms/cm³.

The upper source/drain features 268 are formed after the forming of the gate structures 254. Due to thermal budget concern, the temperature for forming the upper source/drain features 268 is less than about 450° C. Upon completion of this epitaxial growth process, in this depicted example, each upper source/drain feature 268 includes a first upper portion 268a on a sidewall of the channel member 2080U1 in a first channel region (e.g., channel region 210C1), a second upper portion 268b on a sidewall of the channel member 2080U1 in a second channel region (e.g., channel region 210C2), a first lower portion 268c on a sidewall of the channel member 2080U2 in the first channel region, and a second lower portion 268d on a sidewall of the channel member 2080U2 in the second channel region. The portions 268a-268d are not merged. That is, each two portions of the portions 268a-268d are physically separated. The top surfaces of the first and second upper portions 268a-268b may or may not be in contact with the top CESL 250, and the bottom surfaces of the first and second lower portions 268c-268d may or may not be in contact with the bottom CESL 234.

Referring to FIGS. 1B and 16-17, method 100 includes a block 132 where first silicide layers 270 and frontside source/drain contacts 272 are formed. After forming the upper source/drain features 268, with reference to FIG. 16, first silicide layers 270 are formed on the exposed surfaces of the upper source/drain features 268 to reduce a contact resistance between the upper source/drain features 268 and the source/drain contacts 272 thereover. To form the first silicide layer 270, a metal layer (not explicitly shown) is deposited over the substrate 202 and an anneal process is performed to bring about silicidation reaction between the metal layer and the upper source/drain feature 268. Suitable metal layer may include titanium, tantalum, nickel, cobalt, or tungsten. Excessive metal layer that does not form the first silicide layers 270 may be removed. In this illustrated embodiment, the first silicide layer 270 includes a first upper portion 270a extending along an exposed surface of the first upper portion 268a, a second upper portion 270b extending along an exposed surface of second upper portion 268b, a first lower portion 270c extending along an exposed surface of the first lower portion 268c, and a second lower portion 270d extending along an exposed surface of the second lower portion 268d. Two laterally adjacent portions of the portions 270a-270d are not merged. The top surfaces of the first and second upper portions 270a-270b may be in contact with or may be separated from the top CESL 250, and the bottom surfaces of the first and second lower portions 270c-270d may be in contact with or may be separated from the bottom CESL 234. In this illustrated embodiment, each of the portions 270a-270d extends along a top surface, a bottom surface, and one of the two sidewalls of the corresponding portion (e.g., 268a/268b/268c/268d) of the upper source/drain feature 268. Thus, contact resistance may be advantageously reduced.

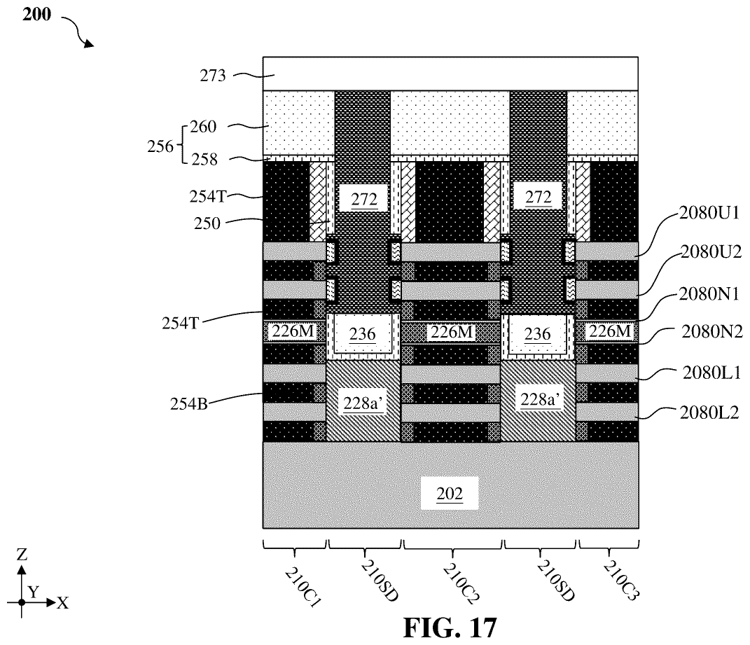

With reference to FIG. 17, source/drain contacts 272 are formed in the first trenches 264′. In an exemplary process, a conductive layer is deposited over the substrate 202 and on the first silicide layers 270 to substantially fill remaining portions of the first trenches 264′. The conductive layer may include aluminum (Al), copper (Cu), tungsten (W), cobalt (Co), ruthenium (Ru), or molybdenum (Mo) or other suitable materials and may be formed by any suitable deposition processes (e.g., CVD). In some embodiments, before forming the conductive layer, a conductive barrier layer (e.g., Ti, Ta, TiN, TaN, other suitable materials, or combinations thereof) may be conformally deposited over the substrate 202, include in the first trenches 264′. A planarization process, such as a chemical mechanical polish (CMP) process, may be then performed to remove excess portions of the conductive layer (and the conductive barrier layer, if any) to form the source/drain contacts 272 in the first trenches 264′. In this illustrated embodiment, a bottom surface of the source/drain contact 272 is below a bottom surface of the upper source/drain feature 268 and is in direct contact with the bottom CESL 234 and the bottom ILD layer 236. Since the source/drain contacts 272 are formed over the top surface of the substrate 202, the source/drain contacts 272 may be referred to as frontside source/drain contacts 272.

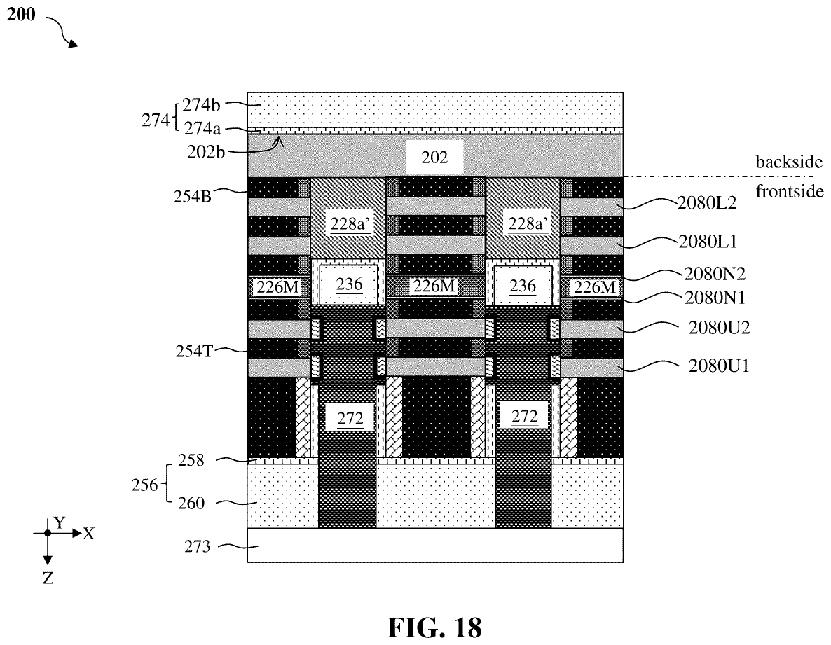

Referring to FIGS. 1B and 17-18, method 100 includes a block 134 where the intermediate structure 200 is flipped over. With reference to FIG. 17, after forming the frontside source/drain contacts 272, various features such as gate vias, source/drain vias, and a multi-layer interconnect structure 273 may be formed over the front side of the transistors. The multi-layer interconnect structure 273 may include a number of conductive features (e.g., metal lines and/or vias) configured to interconnect various components of the transistors with additional features. The conductive features of the multi-layer interconnect structure 273 may be disposed in and/or separated by intermetal dielectric (IMD) layers. The conductive features of the multi-layer interconnect structure 273 may include metal lines/contacts formed on or over the frontside source/drain vias or the gate vias. Each conductive feature of the multi-layer interconnect structure 273 may be formed of metal, such as aluminum, tungsten, ruthenium, or copper. Each IMD layer may include a low-k dielectric material, silicon oxide, other suitable dielectric materials, or combinations thereof, and may be formed by spin-on-glass, flowable CVD (FCVD), other suitable methods, or combinations thereof. With reference to FIG. 18, the intermediate structure 200 is flipped over. After forming the multi-layer interconnect structure 273 over the front side of the substrate 202, a carrier substrate (not shown) may be bonded to the multi-layer interconnect structure 273, and the intermediate structure 200 is then flipped over. In some embodiments, a thinning process may be performed to thin the substrate 202 from its backside to reduce a total thickness of the intermediate structure 200. The thinning process may include a mechanical grinding process and/or a chemical thinning process. For example, a substantial amount of substrate material may be removed from the substrate 202 during a mechanical grinding process. After the thinning down process, the substrate 202 has a bottom surface 202b. For case of description, the positional relationships (e.g., over, below, above, under) of features of the flipped-over intermediate structure 200 will be described in accordance with the figures. For example, as shown in FIGS. 18, after the intermediate structure 200 is flipped over, the substrate 202 is disposed over the channel members 2080U1-2080U2.

Referring to FIGS. 1B and 18, method 100 includes a block 136 where a second dielectric structure 274 is formed over a back side of the substrate 202. In the present embodiment, to provide an end point for a subsequent planarization process, the second dielectric structure 274 includes a first layer 274a and a second layer 274b having a material composition different than the first layer 274a. In an embodiment, the first layer 274a includes a nitride layer (e.g., silicon nitride), and the second layer 274b includes an oxide layer (e.g., silicon oxide).

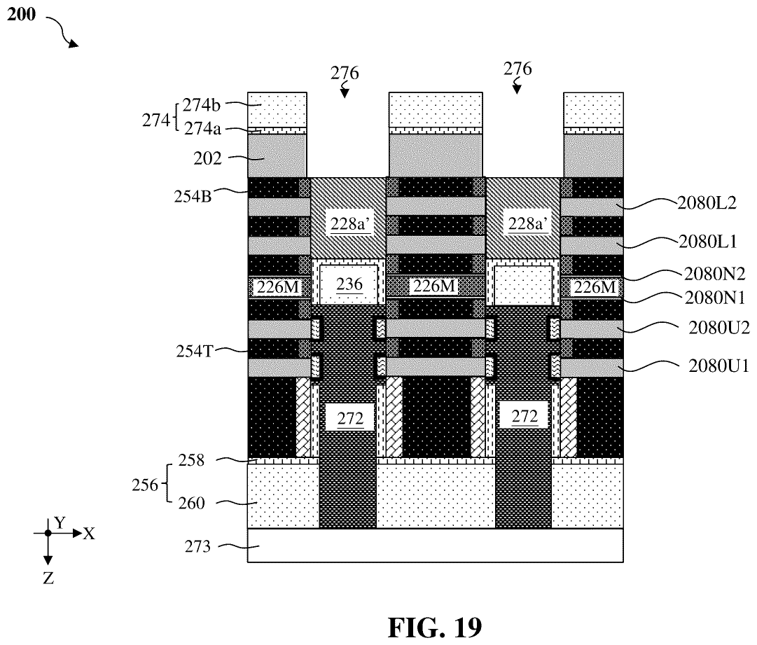

Referring to FIGS. 1B and 19, method 100 includes a block 138 where second trenches 276 are formed to extend through the second dielectric structure 274. In an embodiment, a masking element is formed over the backside of the second dielectric structure 274. The masking element may include openings directly over the backside of the lower portions 228a′ of the first dummy layers 228′. While using the masking element as an etch mask, an etching process is performed to form the second trenches 276. In this illustrated embodiment, the second trenches 276 also extend through the substrate 202 and expose the bottom surfaces of the lower portions 228a′ of the first dummy layers 228′.

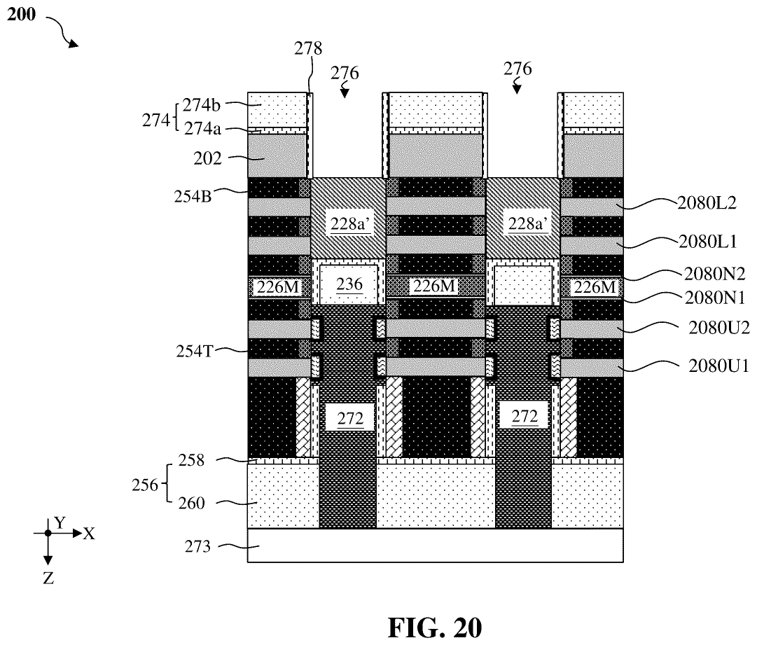

Referring to FIGS. 1B and 20, method 100 includes a block 140 where dielectric liners 278 are formed in the second trenches 276. After the formation of the second trenches 276, a dielectric barrier layer is conformally deposited over the backside of the substrate 202, including in the second trenches 276. The dielectric barrier layer is then etched back to only cover sidewalls of the second trenches 276 and expose the bottom surface of the source/drain features 114N and the bottom surfaces of the lower portions 228a′ of the first dummy layers 228′. The etched back dielectric barrier layer forms the dielectric liners 278 in the second trenches 276. In some embodiments, the dielectric liners 278 may include silicon nitride or other suitable materials. The dielectric liners 278 may be in direct contact with the bottommost inner spacer feature 226.

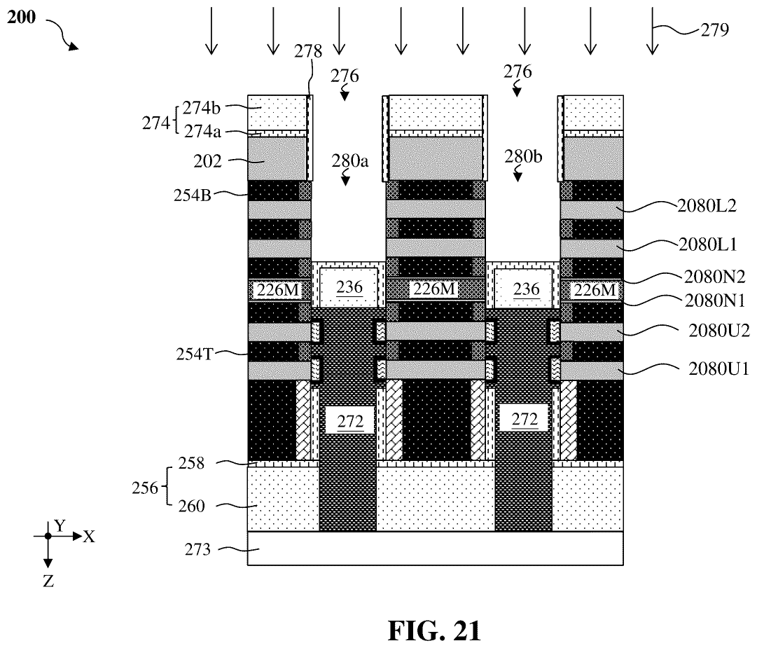

Referring to FIGS. 1B and 21, method 100 includes a block 142 where the lower portions 228a′ of the first dummy layers 228′ are selectively removed to form third trenches 280a-280b. With the exposure of the bottom surfaces of the lower portions 228a′ of the first dummy layers 228′, a third etching process 279 is performed to selectively remove the lower portions 228a′ of the first dummy layers 228′ without substantially etching the lower channel members 2080L1-2080L2 and inner spacer features 226. Etchant of the third etching process 279 may not substantially etch the second dielectric structure 274, the bottom CESL 234, and the dielectric liner 278. In an embodiment, the third etching process 279 is an isotropic etching process.

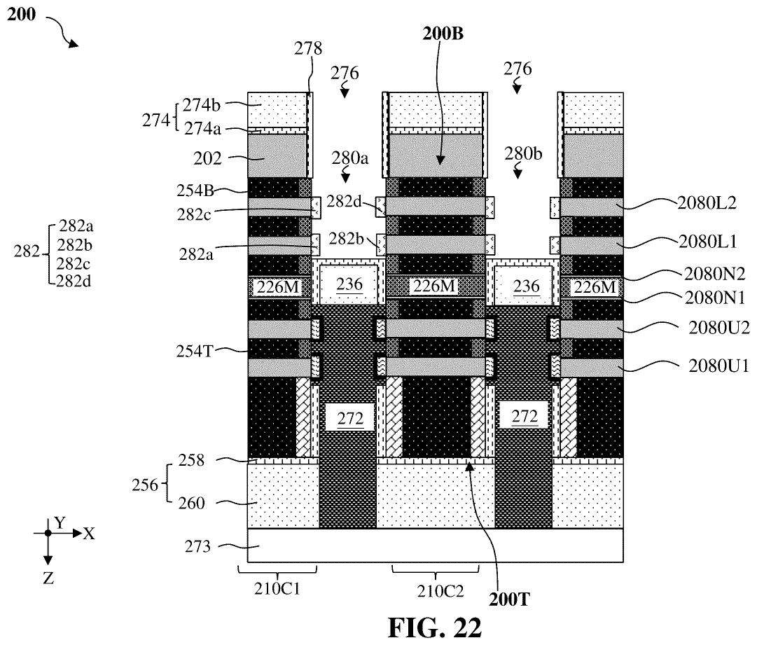

Referring to FIGS. 1B and 22, method 100 includes a block 144 where lower source/drain features 282 are formed in the third trenches 280a-280b. The selective removal of the lower portions 228a′ of the first dummy layers 228′ exposes sidewalls of the lower channel members 2080L1-2080L2. Lower source/drain features 282 are then formed in the third trenches 280a-280b using an epitaxial process, such as VPE, UHV-CVD, MBE, and/or other suitable processes. The epitaxial growth process may use gaseous and/or liquid precursors, which interact with the composition of the lower channel members 2080L1-2080L2. As illustrated in FIG. 22, the lower source/drain features 282 are in physical contact with (or adjoining) the lower channel members 2080L1-2080L2. Depending on the design, the lower source/drain features 282 may be n-type or p-type. In the depicted embodiments, the lower source/drain features 282 are p-type source/drain features and may include germanium, gallium-doped silicon germanium, boron-doped silicon germanium, or other suitable material and may be in-situ doped during the epitaxial process by introducing a p-type dopant, such as boron or gallium, or ex-situ doped using a junction implant process. A dopant concentration of the lower source/drain features 282 may be greater than about 5E20 atoms/cm³.

The lower source/drain features 282 are formed after the forming of the gate structures 254 and the multi-layer interconnect structure 273. Due to thermal budget concern, temperature for forming the lower source/drain features 282 may be less than about 400° C. The temperature for forming the lower source/drain features 282 may be equal to or lower than the temperature for forming the upper source/drain features 268. Upon completion of this epitaxial growth process, in this depicted example, each lower source/drain features 282 includes a first upper portion 282a on a sidewall of the channel member 2080L1 in one channel region (e.g., the channel region 210C1), a second upper portion 282b on a sidewall of the channel member 2080L1 in another channel region (e.g., the channel region 210C2), a first lower portion 282c on a sidewall of the channel member 2080L2 in the one channel region (e.g., the channel region 210C1), and a second lower portion 282d on a sidewall of the channel member 2080L2 in the another channel region (e.g., the channel region 210C2). The portions 282a-282d are not merged. The portions 282a-282b may be in contact with or separated from the bottom CESL 234. The formation of the lower source/drain features 282 indicates the formation of a CFET device including a bottom multi-gate transistor 200B and a top multi-gate transistor 200T.

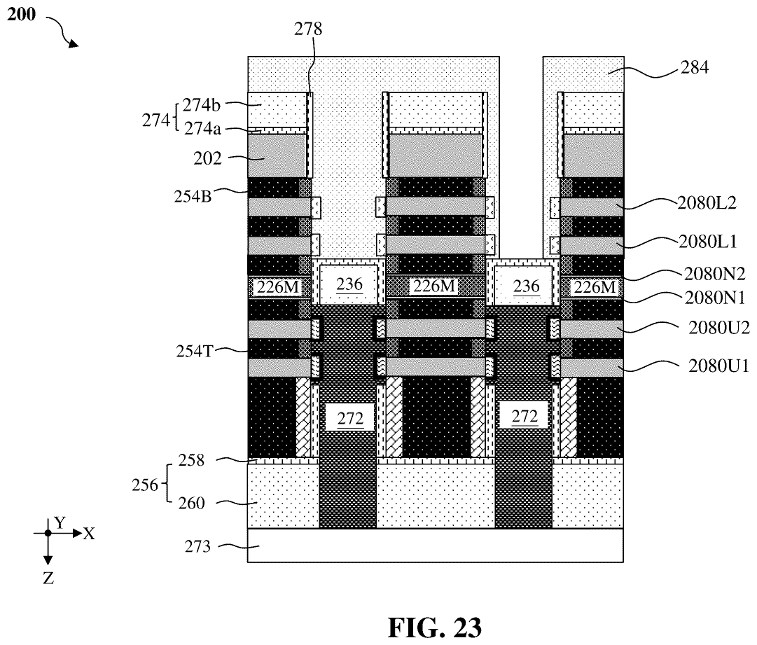

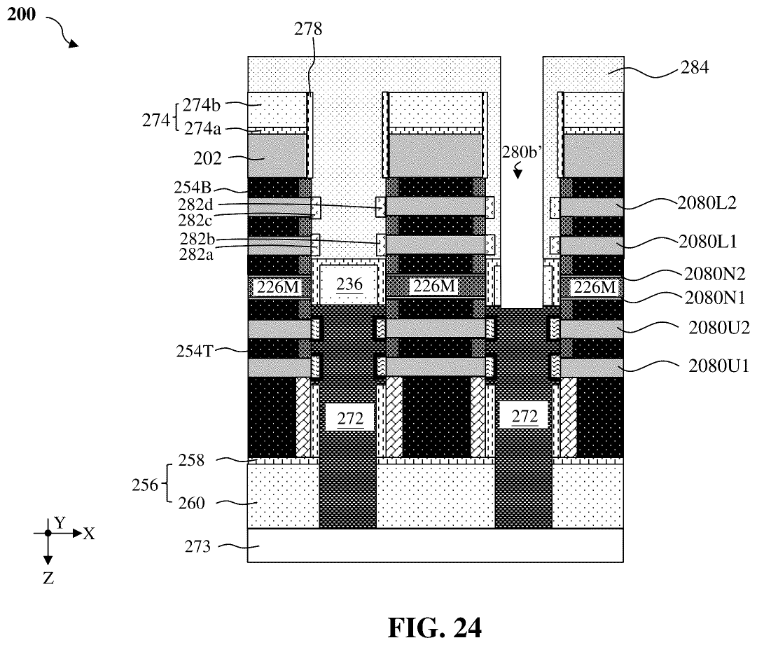

Referring to FIGS. 1B and 23-24, method 100 includes a block 146 where one of the third trenches 280a-280b is further vertically extended to expose one of the frontside source/drain contacts 272. In this illustrated embodiment, one of the source/drain feature (e.g., lower source/drain feature 282) of the bottom multi-gate transistor 200B will be electrically coupled to one of the source/drain feature (e.g., the upper source/drain feature 268) of the top multi-gate transistor 200T. To achieve this electrical connection, a backside source/drain contact having a greater depth is formed. With reference to FIG. 23, after forming the lower source/drain features 282, a protection layer 284 is formed over the backside of the substrate 202 and substantially fills one of the third trenches 280a-280b (e.g., the third trench 280a). The protection layer 284 also partially fills the another one (e.g., the third trench 280b) of the third trenches 280a-280b without fully covering the bottom surface of the bottom CESL 234 exposed by the third trench 280b. Then, with reference to FIG. 24, while using the protection layer 284 as an etch mask, an etching process is performed to further vertically extend the third trench 280b. The vertically extended trench 280b is referred to as the third trench 280b′. The etching process at block 146 removes portions of the bottom ILD layer 236 and the bottom CESL 234 not covered by the protection layer 284. The third trench 280b′ exposes a bottom surface of one of the source/drain contacts 272. That is, the third trench 280b′ spans a depth greater than the third trench 280a. The protection layer 284 will be removed after forming the third trench 280b′.

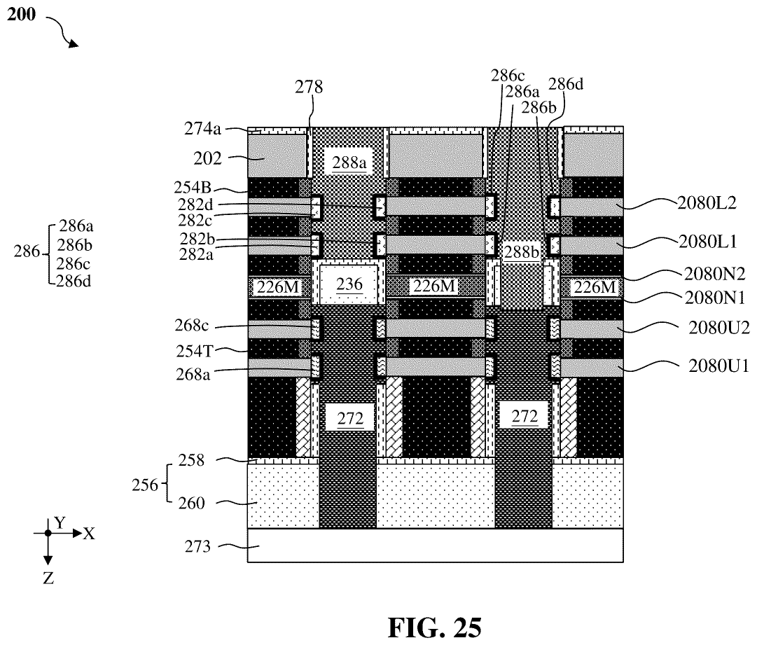

Referring to FIGS. 1B and 25, method 100 includes a block 148 where second silicide layers 286 and backside source/drain contacts 288a-288b are formed. After forming the third trench 280b′, second silicide layers 286 are formed on the exposed surfaces of the lower source/drain features 282 to reduce a contact resistance between the lower source/drain features 282 and the backside source/drain contacts 288a-288b. The formation of the second silicide layer 286 may be similar to that of the first silicide layer 270, and repeated description is omitted for reason of simplicity. In this embodiment, each of the second silicide layers 286 includes a first upper portion 286a extending along exposed surface of the first upper portion 282a, a second upper portion 286b extending along exposed surface of second upper portion 282b, a first lower portion 286c extending along exposed surface of the first lower portion 282c, and a second lower portion 286d extending along exposed surface of the second lower portion 282d. The first and second upper portions 286a-286b may be in contact with or may be separated from the bottom CESL 234. In this illustrated cross-sectional view, each of the portions 286a-286d extends along a top surface, a bottom surface, and one of the two opposite sidewalls of the corresponding portion (e.g., 282a/282b/282c/282d) of the lower source/drain feature 282. Thus, contact resistance may be advantageously reduced.

After forming the second silicide layers 286, a backside source/drain contact 288a and a backside source/drain contact 288b are formed. In an exemplary process, the formation of the backside source/drain contacts 288a-288b may include depositing a conductive layer (e.g., aluminum, rhodium, ruthenium, copper, iridium, or tungsten) over the bottom surface of the intermediate structure 200 to fill the trenches 276, 280a, and 280b′ and performing a planarization process (e.g., chemical mechanical polish (CMP) process) to remove excess materials and the second layer 274b. The planarization process stops on the bottom surface of the first layer 274a. Each of the backside source/drain contact 288a and the backside source/drain contact 288b is electrically coupled to a corresponding lower source/drain feature 282 by way of the second silicide layer 286. The backside source/drain contact 288b also electrically couples to and is in direct contact with the frontside source/drain contact 272. Further processes may be performed to the intermediate structure 200 to form a final structure.

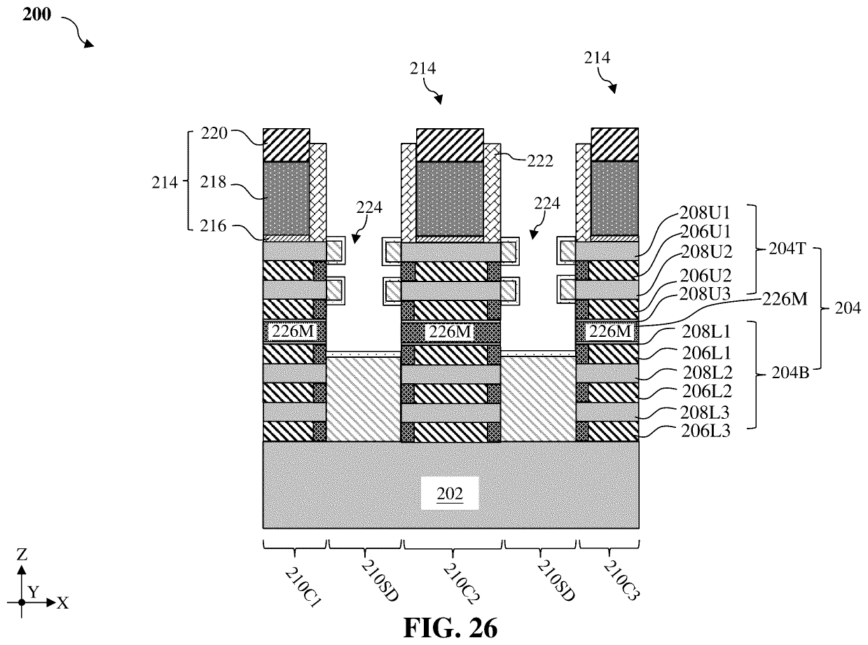

In the above embodiments described with reference to FIG. 7, the oxide layer 230 is formed by a deposition process, such as ALD, thermal ALD, or PEALD. In another alternative embodiment represented by FIG. 26, a thermal oxidization process may be performed to form an oxide layer 230′. The thermal oxidization process may be performed in an oxygen-containing environment and at a processing temperature ranging from about 25° C. to about 900° C. If the processing temperature is lower than 25° C. the oxide layer 230′ may not be substantially formed; and if the processing temperature is higher than 900° C., some features of the intermediate structure 200 may melt. The oxide layer 230′ is formed at the exposed surfaces 228s of the first dummy layer 228 and does not extend along surfaces of dielectric features (e.g., the gate-top hard mask layer 220, the gate spacers 222, and the inner spacer features 226). In an embodiment, a thickness of the oxide layer 230′ may be less than about 10 nm. In an embodiment, the thermal oxidization process for forming the oxide layer 230′ and the thermal treatment 232 (e.g., anneal process) are performed in-situ (e.g., in a same process chamber). For example, after performing the thermal oxidization process for forming the oxide layer 230′, oxygen source configured to provide the oxygen-containing environment will be turned off, and the thermal treatment 232 is then performed in the same process chamber.

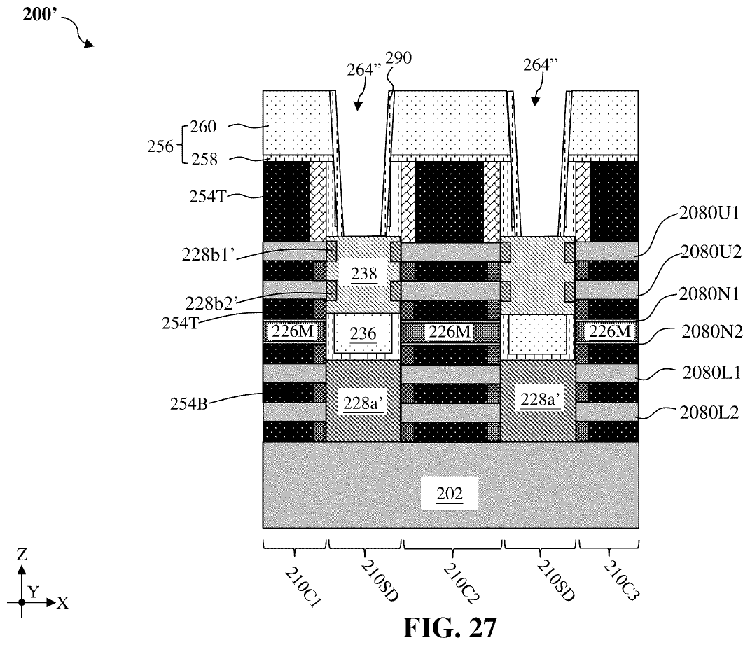

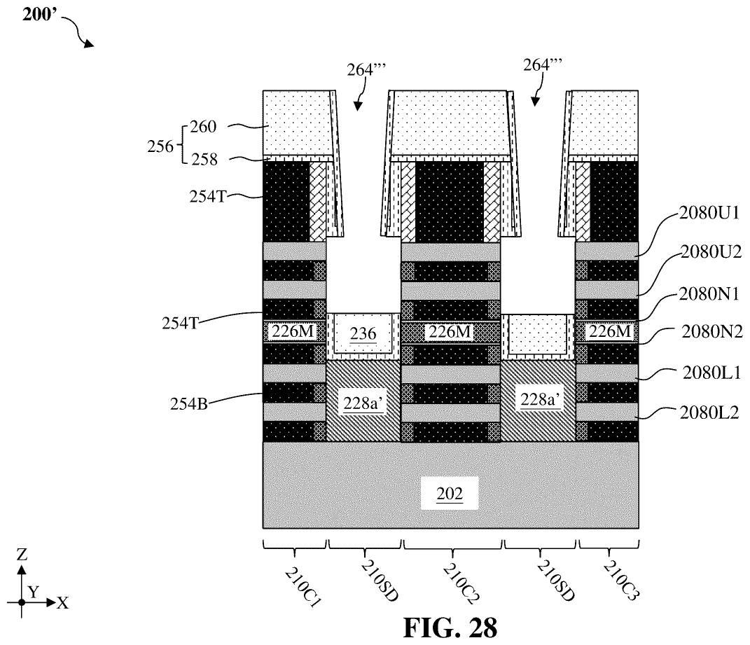

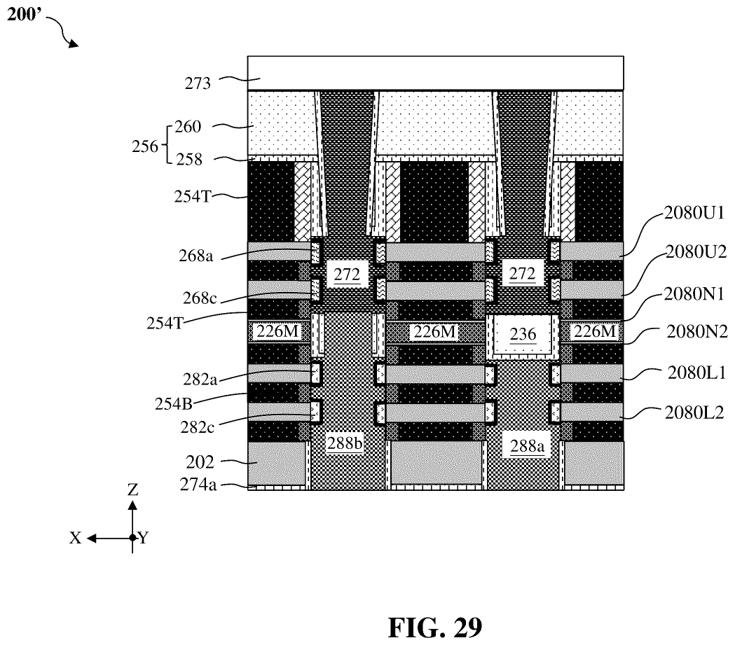

In the above embodiments described with reference to FIGS. 15-16, the first etching process 262 and the second etching process 266 are performed to form the first trench 264′. The first trenches 264′ may also be formed in a different way and have a different profile. This different first trenches 264′ may be referred to as first trenches 264′″. FIGS. 27-29 depict fragmentary cross-sectional view of an alternative intermediate structure 200′ including the first trenches 264′″ during various fabrication stages in the method 100, according to various aspects of the present disclosure. With reference to FIG. 1B and FIGS. 13 and 27, method 100 includes the block 124. The intermediate structure 200 represented by FIG. 13 may be named as the intermediate structure 200′ in this alternative embodiment. Then, with reference to FIGS. 1B and 27, method 100 includes the block 126. In this alternative embodiment, an etching process is performed to form trenches 264″ to expose top surfaces of the second dummy layers 238. Different from the first trenches 264 shown in FIG. 14, the trenches 264″ in this alternative embodiment only extends through the first dielectric structure 256. After forming the trenches 264″, dielectric liners 290 may be formed to extend along sidewall surfaces of the trenches 264″. The composition and formation of the dielectric liners 290 may be similar to those of the dielectric liners 278, and repeated description is omitted for reason of simplicity. With reference to FIGS. 1B and 28, method 100 includes the block 128. After forming the trenches 264″, another etching process is performed to selectively remove the second dummy layers 238 and the upper portion 228b′ of the first dummy layers 228′. The another etching process may be similar to the second etching process 266. The removal of the second dummy layers 238 and the upper portion 228b′ of the first dummy layers 228′ enlarges the lower portions of the trenches 264″. The trenches 264″ after the removal of the second dummy layers 238 and the upper portion 228b′ of the first dummy layers 228′ may be referred to as the first trenches 264′″. Operations at blocks 130-148 are then performed to finish the fabrication of the intermediate structure 200′. FIG. 29 depicts a fragmentary cross-sectional view of the intermediate structure 200′ upon completion of operations in method 100. The intermediate structure 200′ represented by FIG. 29 is substantially similar to the intermediate structure 200 represented by FIG. 25, one of the differences includes that the frontside source/drain contacts 272 in the two structures 200 and 200′ having different profiles due to the different first trenches 264′ and 264′″.

FIG. 30 depicts another alternative method 300 for forming a CFET device with enhanced strain. Referring to FIG. 30, method 300 includes blocks 102, 104, 106, and 108. Operations at blocks 102-108 have been described above, and repeated description is omitted for reason of simplicity. The intermediate structure 200 represented by FIG. 5 is referred to as an intermediate structure 400 in this alternative embodiment. Referring to FIGS. 30 and 31, method 300 includes a block 110′ where first layers 428 are formed in the source/drain openings 224. The formation and composition of the first layers 428 are similar to those of the first dummy layers 228, and one of the differences includes that, the first layers 428 include a p-type dopant and may include germanium, gallium-doped silicon germanium, boron-doped silicon germanium, or other suitable material and may be in-situ doped during the epitaxial process by introducing a p-type dopant, such as boron or gallium, or ex-situ doped using a junction implant process.

In this illustrated embodiment, the first layers 428 includes a lower portion 428a epitaxially grown from the exposed top surface of the substrate 202 and the exposed sidewalls of the lower channel layers 208L2 and 208L3 and an upper portion 428b epitaxially grown from the exposed sidewalls of the upper channel layers 208U1-208U2. As represented by FIG. 31, the lower portion 428a of the first layer 428 substantially fills a lower portion of the source/drain opening 224. The lower portion 428a extends from one channel region (e.g., channel region 210C1) to another channel region (e.g., channel region 210C2). In this illustrated embodiment, the upper portion 428b includes two first parts 428bl and 428b3 on the exposed sidewalls of the channel layers 208U1 in the channel regions 210C1 and 210C2 and two second parts 428b2 and 428b4 on the exposed sidewalls of the channel layers 208U2 in the channel regions 210C1 and 210C2. The two first parts 428b1 and 428b3 are not merged, the two second parts 428b2 and 428b4 are not merged. The lower portion 428a may function as a p-type source/drain feature for the bottom multi-gate transistor, and the upper portion 428b may be removed and replaced by an n-type source/drain feature of the top multi-gate transistor.

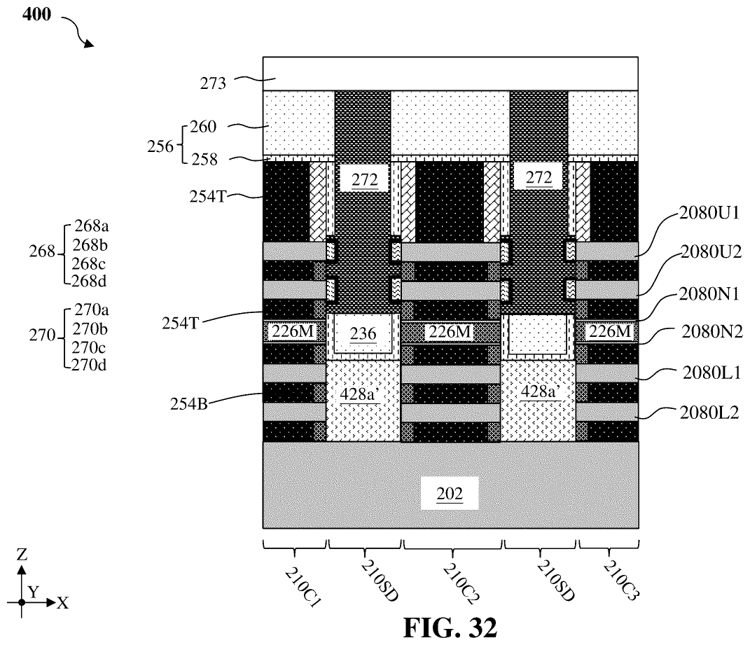

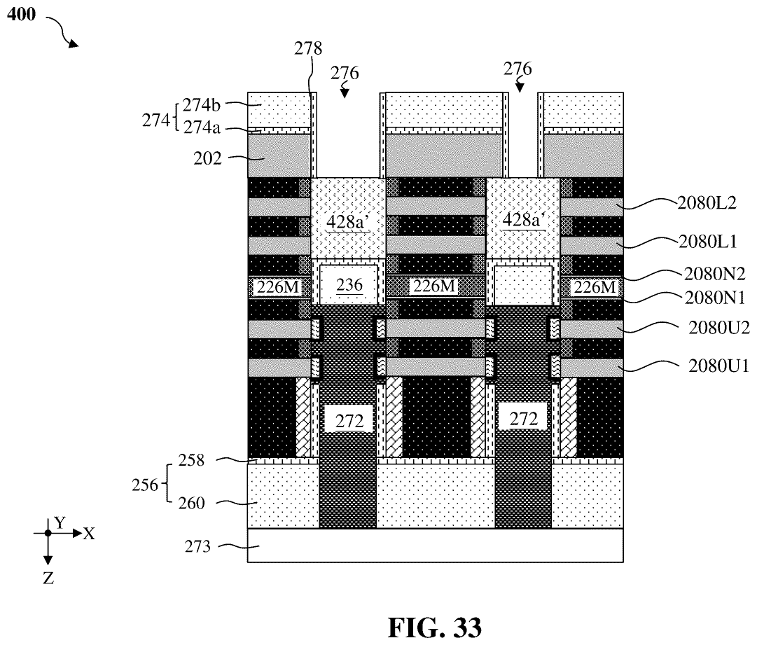

Referring to FIGS. 30 and 32-33, method 300 includes the block 112, 114, 116, 118, 120, 122, 124, 126, 128, 130, 132, 134, 136, and 138. Operations at blocks 112-138 have been described above, and repeated description is omitted for reason of simplicity. It is noted that, operations performed at blocks 112-114 increase germanium concentration of both the lower portion 428a and the upper portion 428b of the first layer 428. The lower portion 428a having the increased germanium concentration is referred to as the lower portion 428a′ or the lower source/drain feature 428a′. Thus, compressive strain induced to the lower channel members 2080L1-2080L2 and tensile strain induced to upper channel members 2080U1-2080U2 may be increased. FIG. 32 depicts a fragmentary cross-sectional view of the intermediate structure 400 upon completion of the operations at blocks 112-134, and FIG. 33 depicts a fragmentary cross-sectional view of the intermediate structure 400 upon completion of the operations at blocks 136 and 138. The intermediate structure 400 represented by FIG. 32 is substantially similar to the intermediate structure 200 represented by FIG. 17, and one difference includes that the second trenches 276 of the intermediate structure 400 expose the p-type doped lower portion 428a′.

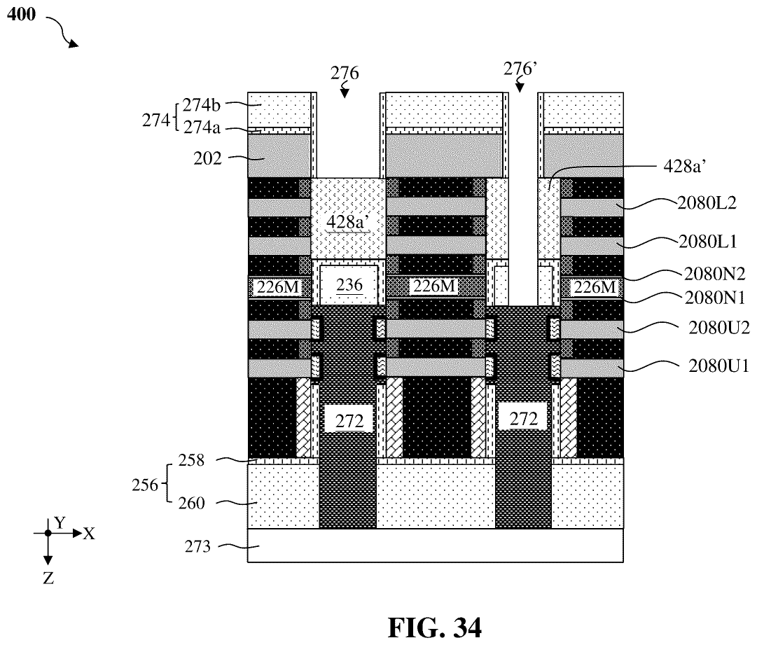

Referring to FIGS. 30 and 34, method 300 includes a block 140′ where one of the second trenches 276 are vertically extended to expose one of the frontside source/drain contacts 272. In an exemplary process, a protection layer (not shown) is formed over the backside of the substrate 202 and substantially covers one of the second trenches 276. While using the protection layer as an etch mask, an etching process is performed to further vertically extend the another one of the second trenches 276 not being fully covered by the protection layer, thereby forming an extended second trench 276′. As illustrated by FIG. 34, the extended second trench 276′ extends through one of the lower portions 428a′, the bottom CESL 234 and the bottom ILD layer 236, and exposes one of the frontside source/drain contacts 272. The protection layer may be selectively removed after forming the extended second trench 276′.

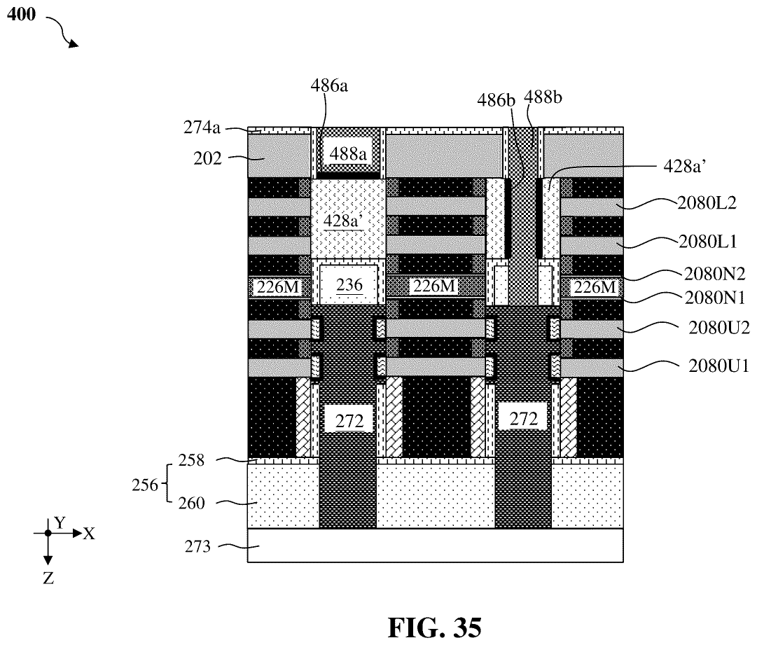

Referring to FIGS. 30 and 35, method 300 includes a block 142′ where silicide layers 486a-486b and backside source/drain contacts 488a and 488b are formed in the second trench 276 and the extended second trench 276′. Operations at block 142′ are similar to operations at block 148 described above, and repeated description is omitted for reason of simplicity. In this embodiment, the silicide layer 486a is formed on the bottom surface of the lower portion 428a′ (e.g., a drain) and in the second trench 276. The silicide layer 486b is formed on exposed sidewall surface of two parts of another lower portion 428a′ (e.g., a source) and in the extended second trench 276′.

Although not intended to be limiting, one or more embodiments of the present disclosure provide many benefits to a semiconductor device and the formation thereof. For example, the present disclosure provides a CFET device having a top multi-gate device and a bottom multi-gate device. In an embodiment, the top multi-gate device is a n-type transistor, and the bottom multi-gate device is a p-type transistor. Compressive strain is induced to channel members of the p-type transistor, and tensile strain is induced to channel members of the n-type transistor. Thus, performance of both p-type transistor and n-type transistor may be improved.

The present disclosure provides for many different embodiments. Semiconductor structures and methods of fabrication thereof are disclosed herein. In one exemplary aspect, the present disclosure is directed to a method. The method includes forming a semiconductor layer stack over a substrate, the semiconductor layer stack having an upper channel layer over a lower channel layer, forming a semiconductor layer, the semiconductor layer comprising a lower portion inducing a compressive strain to the lower channel layer and an upper portion inducing a tensile strain to the upper channel layer, wherein the lower portion is spaced apart from the upper portion, after the forming of the semiconductor layer, forming a first gate structure wrapping around the upper channel layer and a second gate structure wrapping around the lower channel layer, removing the upper portion of the semiconductor layer, and after the forming of the first gate structure and the second gate structure, forming a source/drain feature coupled to the upper channel layer.

In some embodiments, the upper channel layer and the lower channel layer may include silicon, and the semiconductor layer may include silicon germanium. In some embodiments, the lower portion spans a first width, the upper portion spans a second width less than the first width. In some embodiments, the method may also include, after the forming of the semiconductor layer, forming an oxide layer over the semiconductor layer, performing a thermal treatment to the semiconductor layer, thereby increasing a germanium concentration of the semiconductor layer, and selectively removing the oxide layer after the performing of the thermal treatment. In some embodiments, the semiconductor layer may include silicon germanium, and the performing of the thermal treatment forms silicon oxide. In some embodiments, the forming of the oxide layer may include performing a deposition process or a thermal oxidization process. In some embodiments, the removing of the upper portion of the semiconductor layer may include forming an isolation structure disposed between the lower portion and the upper portion of the semiconductor layer, forming a dielectric structure over the first and second gate structures, forming a trench extending through the dielectric structure, and selectively removing the upper portion of the semiconductor layer. In some embodiments, the method may also include forming a silicide layer coupled to the source/drain feature and forming a source/drain contact electrically coupled to the source/drain feature, and a portion of the source/drain contact is disposed under the source/drain feature. In some embodiments, the silicide layer extends along a sidewall surface and a bottom surface of the source/drain feature. In some embodiments, the method may also include removing the lower portion of the semiconductor layer and forming another source/drain feature coupled to the lower channel layer, and the another source/drain feature is a p-type source/drain feature.

In another exemplary aspect, the present disclosure is directed to a method. The method includes forming a first channel layer and a second channel layer over a substrate, the first channel layer and the second channel layer being laterally separated, epitaxially growing a dummy layer over the substrate, the dummy layer comprising a first portion on a sidewall surface of the first channel layer and a second portion on a sidewall surface of the second channel layer, the first portion and the second portion being separated by a spacing, and a composition of the dummy layer being different from a composition of the first and second channel layers, forming an oxide layer extending over the dummy layer, performing a thermal treatment to the oxide layer and the dummy layer, after the performing of the thermal treatment, selectively removing the oxide layer and the dummy layer, and forming a source/drain feature coupled to the first channel layer and the second channel layer.

In some embodiments, the dummy layer may include silicon germanium, and the performing of the thermal treatment increases a germanium concentration of the dummy layer and increases a thickness of the oxide layer. In some embodiments, the method may also include forming a gate structure wrapping around the first channel layer, the source/drain feature is formed after the forming of the gate structure. In some embodiments, the source/drain feature may include a first part on the sidewall surface of the first channel layer and a second part on the sidewall surface of the second channel layer, the first part and the second part are separated. In some embodiments, the method may also include forming a source/drain contact over the substrate and electrically coupled to the source/drain feature, the source/drain contact is disposed between the first part and second part of the source/drain feature. In some embodiments, a bottom surface of the source/drain contact is below a bottom surface of the source/drain feature.

In yet another exemplary aspect, the present disclosure is directed to a semiconductor device. The semiconductor device includes a lower source/drain feature disposed over a substrate, a first nanostructure coupled to the lower source/drain feature, a first gate structure wrapping around the first nanostructure, an upper source/drain feature over the lower source/drain feature, a second nanostructure coupled to the upper source/drain feature, a second gate structure wrapping around the second nanostructure, and a source/drain contact over the substrate and electrically coupled to the upper source/drain feature, a bottom surface of source/drain contact is below a bottom surface of the upper source/drain feature.

In some embodiments, the semiconductor device may also include an isolation structure disposed between the lower source/drain feature and the upper source/drain feature, and the upper source/drain feature is spaced apart from the isolation structure. In some embodiments, the bottom surface of the source/drain contact has a first width, a bottom surface of the upper source/drain feature has a second width less than the first width. In some embodiments, the semiconductor device may also include a transistor disposed adjacent to the second gate structure, and the source/drain contact extends between the upper source/drain feature and a source/drain feature of the transistor.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a semiconductor layer stack over a substrate, the semiconductor layer stack having an upper channel layer over a lower channel layer;
forming a semiconductor layer, the semiconductor layer comprising a lower portion inducing a compressive strain to the lower channel layer and an upper portion inducing a tensile strain to the upper channel layer, wherein the lower portion is spaced apart from the upper portion;
after the forming of the semiconductor layer, forming a first gate structure wrapping around the upper channel layer and a second gate structure wrapping around the lower channel layer;
removing the upper portion of the semiconductor layer; and
after the forming of the first gate structure and the second gate structure, forming a source/drain feature coupled to the upper channel layer.

2. The method of claim 1, wherein the upper channel layer and the lower channel layer comprise silicon, and the semiconductor layer comprises silicon germanium.

3. The method of claim 1, wherein the lower portion spans a first width, the upper portion spans a second width less than the first width.

4. The method of claim 1, further comprising:
after the forming of the semiconductor layer, forming an oxide layer over the semiconductor layer;
performing a thermal treatment to the semiconductor layer, thereby increasing a germanium concentration of the semiconductor layer; and
selectively removing the oxide layer after the performing of the thermal treatment.

5. The method of claim 4, wherein the semiconductor layer comprises silicon germanium, and the performing of the thermal treatment forms silicon oxide.

6. The method of claim 4, wherein the forming of the oxide layer comprises performing a deposition process or a thermal oxidization process.

7. The method of claim 1, wherein the removing of the upper portion of the semiconductor layer comprises:
forming an isolation structure disposed between the lower portion and the upper portion of the semiconductor layer;
forming a dielectric structure over the first and second gate structures;
forming a trench extending through the dielectric structure; and
selectively removing the upper portion of the semiconductor layer.

8. The method of claim 7, further comprising:
forming a silicide layer coupled to the source/drain feature; and
forming a source/drain contact electrically coupled to the source/drain feature, wherein a portion of the source/drain contact is disposed under the source/drain feature.

9. The method of claim 8, wherein the silicide layer extends along a sidewall surface and a bottom surface of the source/drain feature.

10. The method of claim 1, further comprising:
removing the lower portion of the semiconductor layer; and
forming another source/drain feature coupled to the lower channel layer,
wherein the another source/drain feature is a p-type source/drain feature.

11. A method, comprising:
forming a first channel layer and a second channel layer over a substrate, the first channel layer and the second channel layer being laterally separated;
epitaxially growing a dummy layer over the substrate, wherein the dummy layer comprises a first portion on a sidewall surface of the first channel layer and a second portion on a sidewall surface of the second channel layer, the first portion and the second portion are separated by a spacing, and wherein a composition of the dummy layer is different from a composition of the first and second channel layers;
forming an oxide layer extending over the dummy layer;
performing a thermal treatment to the oxide layer and the dummy layer;
after the performing of the thermal treatment, selectively removing the oxide layer and the dummy layer; and
forming a source/drain feature coupled to the first channel layer and the second channel layer.

12. The method of claim 11, wherein the dummy layer comprises silicon germanium, and the performing of the thermal treatment increases a germanium concentration of the dummy layer and increases a thickness of the oxide layer.

13. The method of claim 11, further comprising:
forming a gate structure wrapping around the first channel layer, wherein the source/drain feature is formed after the forming of the gate structure.

14. The method of claim 11, wherein the source/drain feature comprises a first part on the sidewall surface of the first channel layer and a second part on the sidewall surface of the second channel layer, the first part and the second part are separated.

15. The method of claim 14, further comprising:
forming a source/drain contact over the substrate and electrically coupled to the source/drain feature, wherein the source/drain contact is disposed between the first part and second part of the source/drain feature.

16. The method of claim 15, wherein a bottom surface of the source/drain contact is below a bottom surface of the source/drain feature.

17. A semiconductor device, comprising:
a lower source/drain feature disposed over a substrate;
a first nanostructure coupled to the lower source/drain feature;
a first gate structure wrapping around the first nanostructure;
an upper source/drain feature over the lower source/drain feature;
a second nanostructure coupled to the upper source/drain feature;
a second gate structure wrapping around the second nanostructure; and
a source/drain contact over the substrate and electrically coupled to the upper source/drain feature, wherein a bottom surface of source/drain contact is below a bottom surface of the upper source/drain feature.

18. The semiconductor device of claim 17, further comprising:
an isolation structure disposed between the lower source/drain feature and the upper source/drain feature, wherein the upper source/drain feature is spaced apart from the isolation structure.

19. The semiconductor device of claim 18, wherein the bottom surface of the source/drain contact has a first width, a bottom surface of the upper source/drain feature has a second width less than the first width.

20. The semiconductor device of claim 19, further comprising:
a transistor disposed adjacent to the second gate structure,
wherein the source/drain contact extends between the upper source/drain feature and a source/drain feature of the transistor.
